(19) United States
(12) Patent Application Publication
(10) Pub. No.: US 2025/0212590 A1
(43) Pub. Date: Jun. 26, 2025

(54) METHOD FOR MANUFACTURING LIGHT-EMITTING DEVICE, AND LIGHT-EMITTING DEVICE

(71) Applicant: NICHIA CORPORATION, Anan-shi (JP)

(72) Inventors: Shoichi KASHIHARA, Tokushima-shi (JP); Masanobu SATO, Tokushima-shi (JP)

(73) Assignee: NICHIA CORPORATION, Anan-shi (JP)

(21) Appl. No.: 18/985,355

(22) Filed: Dec. 18, 2024

(30) Foreign Application Priority Data
Dec. 21, 2023 (JP) 2023-216271

(51) Int. Cl. H10H 29/856; H10H 29/01; H10H 29/80; H10H 29/851

(52) U.S. Cl. CPC H10H 29/856; H10H 29/0361; H10H 29/0363; H10H 29/851; H10H 29/942

(57) ABSTRACT

A method for manufacturing a light-emitting device includes: preparing an intermediate body including: a substrate, and a plurality of light-emitting elements disposed on the substrate, each including a first surface serving as a light extraction surface, a second surface opposite to the first surface, and a lateral surface connecting the first surface and the second surface; applying a powder composition including a reflective member and a silicone resin powder from above the first surfaces of the plurality of light-emitting elements through a sieve to locate the powder composition on the substrate and between the lateral surfaces of the plurality of light-emitting elements; and forming a first covering member by applying vibration to the powder composition and subsequently applying pressure in a thickness direction of the substrate to perform compression molding.

### CROSS-REFERENCE TO RELATED APPLICATIONS

The present application claims priority under 35 U.S.C. § 119 to Japanese Patent Application No. 2023-216271, filed Dec. 21, 2023, the contents of which are incorporated herein by reference in their entirety.

### BACKGROUND

### 1. Technical Field

The present disclosure relates to a method for manufacturing a light-emitting device and to a light-emitting device.

### 2. Description of Related Art

In recent years, high-output light-emitting devices configured using light-emitting elements such as LEDs as light sources are used, and methods for manufacturing light-emitting devices having various characteristics are proposed. For example, a method for producing an optical assembly by depositing a solid silicone-containing hot melt composition in a powder form on an optical surface of an optical element and forming an encapsulant from the silicone-containing hot melt composition is known, the encapsulant substantially covering the optical surface of the optical element (see Japanese Patent Publication No. 2016-522978, for example).

### SUMMARY

Embodiments of the present disclosure can provide a method for manufacturing a light-emitting device with high luminance and excellent contrast and such a light-emitting device.

A method for manufacturing a light-emitting device according to an embodiment of the present disclosure includes: preparing an intermediate body in which a plurality of light-emitting elements each including a first surface serving as a light extraction surface, a second surface opposite to the first surface, and a lateral surface connecting the first surface and the second surface are disposed on a substrate; applying a powder composition including a reflective member and a silicone resin powder from above the first surfaces of the plurality of light-emitting elements through a sieve to locate the powder composition on the substrate and between the lateral surfaces of the plurality of light-emitting elements; and forming a first covering member by applying vibration to the powder composition and subsequently applying pressure in a thickness direction of the substrate to perform compression molding.

A light-emitting device according to an embodiment of the present disclosure includes: a substrate; a plurality of light-emitting elements mounted on the substrate and each including a first surface serving as a light extraction surface, a second surface opposite to the first surface, and a lateral surface connecting the first surface and the second surface; and a first covering member provided on the substrate and between the lateral surfaces of the plurality of light-emitting elements, wherein the first covering member includes a reflective member and a silicone resin, the silicone resin has a refractive index of 1.45 or less, a density of the reflective member in the first covering member is 2.0 g/cm³ or more, and a reflectance of the first covering member is 70% or more with respect to light at an emission peak of the light-emitting elements.

An embodiment of the present disclosure can provide a method for manufacturing a light-emitting device with high luminance and excellent contrast and such a light-emitting device.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic plan view illustrating an example of a light-emitting device according to a first embodiment.

FIG. 1B is a schematic cross-sectional view taken along line IB-IB in FIG. 1A.

FIG. 2A is a schematic plan view illustrating an example of a light-emitting device according to a second embodiment.

FIG. 2B is a schematic cross-sectional view taken along line IIB-IIB in FIG. 2A.

FIG. 3A is a schematic plan view illustrating an example of a light-emitting device according to a third embodiment.

FIG. 3B is a schematic cross-sectional view taken along line IIIB-IIIB in FIG. 3A.

FIG. 4 is a flowchart showing an example of a method for manufacturing the light-emitting device according to the first embodiment.

FIG. 5A is a schematic cross-sectional view illustrating an example of preparing of an intermediate body in the method for manufacturing the light-emitting device according to the first embodiment.

FIG. 5B is a schematic cross-sectional view illustrating an example of forming of a frame body on a substrate in the method for manufacturing the light-emitting device according to the first embodiment.

FIG. 5C is a schematic cross-sectional view illustrating an example of applying a powder composition in the method for manufacturing the light-emitting device according to the first embodiment.

FIG. 5D is a schematic enlarged cross-sectional view of a region VD in FIG. 5C.

FIG. 5E is a schematic cross-sectional view illustrating an example of applying of vibration to the powder composition in forming of a first covering member in the method for manufacturing the light-emitting device according to the first embodiment.

FIG. 5F is a schematic enlarged cross-sectional view of a region VF in FIG. 5E.

FIG. 5G is a schematic cross-sectional view illustrating an example of compression-molding of the powder composition in the forming of the first covering member in the method for manufacturing the light-emitting device according to the first embodiment.

FIG. 5H is a schematic enlarged cross-sectional view of a region VH in FIG. 5E.

FIG. 6 is a flowchart showing an example of a method for manufacturing a light-emitting device according to a second embodiment.

FIG. 7A is a schematic cross-sectional view illustrating an example of forming of a second covering member in the method for manufacturing the light-emitting device according to the second embodiment.

FIG. 7B is a schematic cross-sectional view illustrating an example of applying a powder composition in the method for manufacturing the light-emitting device according to the second embodiment.

FIG. 7C is a schematic cross-sectional view illustrating an example of forming of a first covering member in the method for manufacturing the light-emitting device according to the second embodiment.

FIG. 7D is a schematic cross-sectional view illustrating an example of performing of polishing or grinding in the method for manufacturing the light-emitting device according to the second embodiment.

FIG. 8 is a flowchart showing an example of a method for manufacturing a light-emitting device according to a third embodiment.

### DETAILED DESCRIPTION

### Description of Embodiments

A method for manufacturing a light-emitting device of an embodiment according to the present invention (hereinafter, may be referred to as a “method for manufacturing a light-emitting device according to an embodiment”) and a light-emitting device (hereinafter, may be referred to as a “light-emitting device according to an embodiment”) are described below with reference to the drawings. Note that, in the following description, terms indicating a specific direction or position (for example, “upper,” “lower,” and other terms including those terms) are used as necessary. The use of those terms, however, is to facilitate understanding of the invention with reference to the drawings, and the technical scope of the present invention is not limited by the meanings of those terms. Parts or members having the same reference signs appearing in a plurality of drawings indicate identical or equivalent parts or members.

The following embodiments exemplify a light-emitting device and a method for manufacturing a light-emitting device to embody the technical concept of the present invention, and the present invention is not limited to the embodiments below. The dimensions, materials, shapes, relative arrangements, and the like of parts or members described below are not intended to limit the scope of the present invention to those alone, but are intended to provide an example, unless otherwise specified. The contents described in one embodiment can be applied to the other embodiments and modified examples. The dimensions, positional relationships, and the like of parts or members illustrated in the drawings may be exaggerated to clarify the explanation. Furthermore, to avoid excessive complication of the drawings, a schematic view in which some parts or members are not illustrated may be used, or an end view illustrating only a cutting surface may be used as a cross-sectional view.

### Light-Emitting Device

A light-emitting device 100 according to an embodiment includes a substrate 11, a plurality of light-emitting elements 12 mounted on the substrate 11 and each having a first surface 12a serving as a light extraction surface, a second surface 12b opposite to the first surface 12a, and a lateral surface 12c connecting the first surface 12a and the second surface 12b, and a first covering member 18 provided on the substrate 11 and between the lateral surfaces 12c of the plurality of light-emitting elements 12. The light-emitting device 100 according to the embodiment preferably further includes a wavelength conversion member 14, a light-transmissive member 15, protective elements 25, and a frame body 150, and may further include other members as necessary.

The related art has proposed a light-emitting device in which a reflective member made of a binder material containing a white pigment is provided on lateral surfaces of a plurality of light-emitting elements provided on a substrate. When the content of the white pigment in the binder material is increased to obtain a light-emitting device with high luminance and excellent contrast, the fluidity of the binder material is lost and spreading the reflective member over the entire surface of the substrate is difficult. In particular, because the distance between the lateral surfaces of the plurality of light-emitting elements is required to be reduced, applying the binder material between the lateral surfaces of the plurality of light-emitting elements without any gap is difficult. When the reflective member is diluted with a solvent to impart fluidity to the binder material, voids or cracks are likely to occur in the reflective member due to volume shrinkage of the solvent during drying.

On the other hand, the light-emitting device 100 according to the embodiment has high luminance and excellent contrast because the first covering member 18 includes a reflective member and a silicone resin, the silicone resin has a refractive index of 1.45 or less, the reflective member in the first covering member 18 has a density of 2.0 g/cm³ or more, and a reflectance of the first covering member 18 is 70% or more with respect to light at the emission peak of the light-emitting elements 12. This can be suitably implemented by the method for manufacturing the light-emitting device according to the embodiment.

### Light-Emitting Device According to First Embodiment

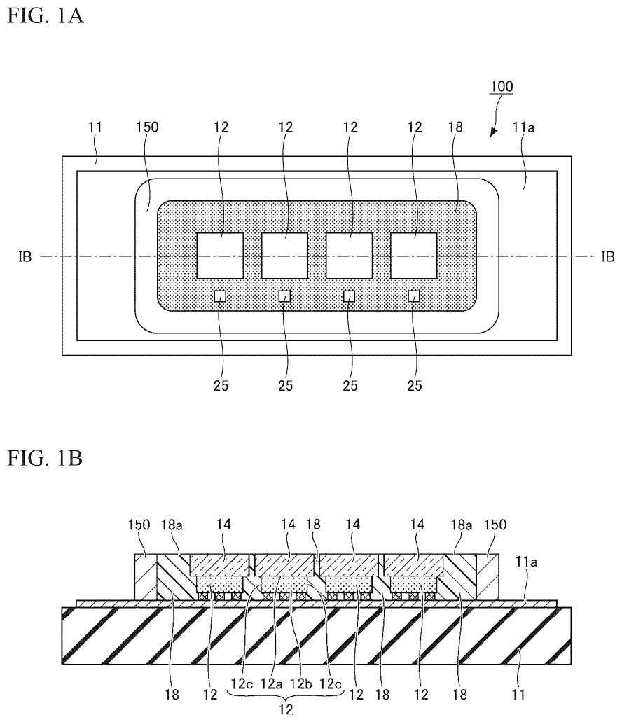

FIG. 1A is a schematic plan view illustrating an example of a light-emitting device according to the first embodiment. FIG. 1B is a schematic cross-sectional view taken along line IB-IB in FIG. 1A.

As illustrated in FIGS. 1A and 1B, the light-emitting device 100 according to the first embodiment includes the substrate 11, the light-emitting element 12, the first covering member 18, the wavelength conversion member 14, the protective element 25, and the frame body 150. Each component of the light-emitting device 100 is described below.

### Substrate

The substrate 11 is a member that supports the light-emitting element 12 and the like. For example, in addition to the light-emitting elements 12, the protective elements 25 are mounted on the substrate 11, and the substrate 11 includes wiring lines 11a electrically connected to electrodes of the light-emitting elements 12 to electrically connect the light-emitting device 100 to the outside.

The planar shape of the substrate 11 can be various shapes such as a circle, an ellipse, a polygon such as a quadrangle or a hexagon, or a polygon with rounded corners. Among these, the planar shape of the substrate 11 is preferably a rectangle. The dimension of the substrate 11 can be appropriately adjusted depending on the required performance such as the dimensions and number of the light-emitting elements 12 to be disposed thereon.

The planar shape of the wiring line 11a can be appropriately set depending on the dimensions, the number, and the like of the light-emitting elements 12 disposed therein.

The main material of the substrate 11 is an insulating material and is preferably a material through which light from the light-emitting element 12 and light from the outside are less likely to be transmitted. Examples of such materials include ceramics such as aluminum oxide and aluminum nitride, and resins such as phenol resins, epoxy resins, silicone resins, polyimide resins, BT resins, and polyphthalamide. When a resin is used, inorganic fillers such as glass fibers, silicon oxide, titanium oxide, and aluminum oxide may be mixed into the resin as necessary. Thus, the mechanical strength can be improved, thermal expansion coefficient can be reduced, and the light reflectance can be improved. The substrate 11 may be obtained by forming an insulating material on a surface of a metal member.

The wiring lines 11a are formed on the insulating material in a predetermined pattern. Examples of the material of the wiring line include metals such as Au, Ag, Cu, Fe, Ti, Pd, Ni, Cr, Pt, W, and Al, and alloys containing these metals. The wiring lines can be formed by plating, vapor deposition, sputtering, or the like. For example, when Au is used for a bonding member to be described below between the light-emitting element and the substrate, Au is preferably used for the outermost surfaces of the wiring lines 11a from the viewpoint of improving the bonding property.

### Light-Emitting Element

The light-emitting element 12 includes the first surface 12a serving as a light extraction surface, the second surface 12b opposite to the first surface 12a, and the lateral surface 12c connecting the first surface 12a and the second surface 12b. The plurality of light-emitting elements 12 are disposed on an upper surface of the substrate 11. In this case, the light-emitting elements 12 may be disposed in a line in a first direction or may be disposed in a matrix. Among these, the light-emitting elements 12 are preferably disposed in a line in the first direction, and more preferably disposed in a line in the first direction as illustrated in FIG. 1A. Thus, the light-emitting device 100 having a horizontally long light distribution pattern suitable for vehicle headlights can be obtained. For example, when the planar shape of the substrate 11 is a rectangle as described above, the plurality of light-emitting elements 12 are preferably disposed in a line along the first direction being a direction in which a long side extends. The plurality of light-emitting elements 12 are preferably disposed in a line at equal intervals.

The planar shape of the first surface 12a serving as a light extraction surface of the light-emitting element 12 or the second surface 12b opposite to the first surface 12a may be various shapes such as a circle, an ellipse, a polygon such as a quadrangle and a hexagon, and a polygon with rounded corners. Among these, the planar shape of the first surface 12a or the second surface 12b of the light-emitting element 12 is preferably quadrangular, more preferably rectangular. Thus, when the plurality of light-emitting elements 12 are arranged in the first direction, the plurality of light-emitting elements 12 can be arranged close to each other with the distance between the lateral surfaces 12c of adjacent light-emitting elements 12 kept constant. In addition, a light-emitting surface having a horizontally long rectangular shape in a plan view can be formed as a whole.

Although the plurality of light-emitting elements 12 are the same in design, an error occurs due to a member tolerance, a mounting tolerance, or the like at the time of manufacturing. In this specification, when “distance,” “width,” “height,” “length,” and “area” are said to be the same, they are not necessarily the same as each other as long as such an error is included in an allowable range.

The vertical and horizontal dimensions of the first surface 12a and the second surface 12b of the light-emitting element 12 and the dimension of the lateral surface 12c (height of the light-emitting element 12) connecting the first surface 12a and the second surface 12b of the light-emitting element 12 can be arbitrarily set. Among these, to implement a higher-output light-emitting device, a large light-emitting element 12 is preferably used, and in a plan view, the vertical and horizontal dimensions of the first surface 12a and the second surface 12b of the light-emitting element 12 are preferably 600 μm or more, more preferably 1,000 μm or more. From the viewpoint of uniformity of light emission intensity, ease of mounting, and the like, the vertical and horizontal dimensions of the first surface 12a and the second surface 12b of the light-emitting element 12 are preferably 2,000 μm or less.

The light-emitting element 12 is spaced apart from an adjacent light-emitting element 12. In this case, the distance between the light-emitting elements 12 is, for example, in a range from 0.1 times to 0.5 times one side of the light-emitting element 12 along the first direction. Specifically, in the case of using light-emitting elements 12 each having a substantially square shape in a plan view in which the longitudinal and horizontal dimensions of the first surface 12a and the second surface 12b of the light-emitting elements 12 are about 1,000 μm, the distance between adjacent light-emitting elements 12 is in a range from 100 μm to 500 km.

A light-emitting diode is preferably used as the light-emitting element 12. The light-emitting element 12 having any wavelength can be selected. Examples of blue or green light-emitting elements 12 include those using a nitride semiconductor (InₓAl_{y}Ga_{1-x-y}N, 0≤x, 0≤y, x+y≤1), ZnSe, and GaP. As a red light-emitting element 12, GaAlAs, AlInGaP, and the like can be used. Moreover, the light-emitting element 12 can also use a semiconductor light-emitting element made of other materials. The composition, emission color, dimensions, and number of the light-emitting elements 12 used can be appropriately selected in accordance with an intended purpose. In a case of a light-emitting device including a phosphor, a light-emitting element 12 made of a nitride semiconductor that can emit light with a short wavelength that can efficiently excite the phosphor is preferably used.

The light-emitting element 12 is formed, for example, by layering a semiconductor layer on a light-transmissive support substrate such as a sapphire substrate for growth, and a support substrate side is the first surface 12a of the light-emitting element 12 and serves as a main light-emitting surface (light extraction surface). The support substrate may be removed by, for example, polishing, laser lift-off, or the like.

The light-emitting element 12 preferably includes, for example, a first electrode and a second electrode on the same surface side, that is, the second surface 12b opposite to the light emission surface. The first electrode and the second electrode are disposed in the light-emitting element 12 such that, for example, the first electrode is disposed in a central portion and the second electrodes are disposed to sandwich the first electrode therebetween.

The light-emitting element 12 is mounted on the substrate 11 such that the second surface 12b provided with the electrodes faces the substrate 11 as a lower surface. Specifically, the first electrode or the second electrode of the light-emitting element 12 is connected to the wiring line 11a provided on the substrate 11 via a bonding member.

Examples of the bonding member include bumps made of Au, Ag, Cu, or alloys including the same, solders such as Sn—Bi based solders, Sn—Cu based solders, Sn—Ag based solders, or Au—Sn based solders, eutectic alloys such as alloys having Au and Sn as main components, alloys having Au and Si as main components, or alloys having Au and Ge as main components, conductive pastes made of Au, Ag, or Pd, anisotropic conductive materials such as ACP and ACF, brazing filler metals made of low melting point metals, conductive adhesives combining these, and conductive composite adhesives. Of these, a bump is preferably used from the viewpoint of positional accuracy. From the viewpoint of bonding strength and heat dissipation, the first electrode and the second electrode are preferably each connected on the substrate 11 via a plurality of bumps.

When the light-emitting element 12 is bonded to the wiring line by the bonding member such as a bump, a gap corresponding to the thickness of the bonding member is generated between the light-emitting element 12 and the substrate 11. At this time, by disposing a first covering member containing a reflective member in the gap, light traveling from the light-emitting element 12 toward the substrate 11 can be reflected and easily extracted externally.

The first surface 12a of the light-emitting element 12 may have polishing or grinding marks. This is because S105 of performing polishing or grinding to be described below is performed in the method for manufacturing the light-emitting device according to the embodiment. However, the polishing or grinding marks on the first surface 12a of the light-emitting device are very fine and do not affect the luminance or contrast of the light-emitting device 100.

### First Covering Member

The first covering member 18 is provided on the substrate 11 and between the lateral surfaces 12c of the plurality of light-emitting elements 12. The first covering member 18 has a first surface (also referred to as an “upper surface 18a of the first covering member 18” or an “exposed surface”) on a side opposite to a surface in contact with the substrate 11. A lateral surface of the first covering member 18 is in contact with the lateral surface 12c of the light-emitting element 12 or in contact with a lateral surface of the frame body 150. In the light-emitting device 100 according to the first embodiment, the upper surface 18a of the first covering member 18 is flush with the first surface 12a of the light-emitting element 12.

The first covering member 18 includes a reflective member and a silicone resin. The first covering member 18 is formed on the substrate 11 to cover the lateral surfaces 12c of the plurality of light-emitting elements 12 with a powder composition containing a reflective member and silicone resin powder, for example. That is, because the first covering member 18 covers the substrate 11, the lateral surfaces 12c of the plurality of light-emitting elements 12, and a lateral surface of the wavelength conversion member 14, the lateral surface of the first covering member is in contact with the lateral surface 12c of the light-emitting element 12. Accordingly, the first covering member 18 covers outer peripheral lateral surfaces of the plurality of light-emitting elements 12 and an outer peripheral lateral surface of the wavelength conversion member 14. When the light-emitting device 100 includes the light-transmissive member 15, because the first covering member 18 further covers an outer peripheral lateral surface of the light-transmissive member 15, the lateral surface of the first covering member 18 is in contact with the lateral surface of the light-transmissive member 15. When the light-emitting device 100 includes the frame body 150, the first covering member 18 is provided on the substrate 11, between the lateral surfaces 12c of the plurality of light-emitting elements 12, and between the lateral surfaces 12c of the plurality of light-emitting elements 12 and the lateral surface of the frame body 150 in the frame body 150, and the lateral surface of the first covering member 18 is in contact with the lateral surfaces 12c of the light-emitting elements 12 and the lateral surface of the frame body 150.

Examples of the reflective material used for the first covering member 18 include titanium oxide, silica, silicon oxide, aluminum oxide, zirconium oxide, magnesium oxide, potassium titanate, zinc oxide, and boron nitride. These may be used alone or in combination of two or more. Among these, titanium oxide having a relatively high light reflectance and refractive index is preferably used.

Examples of the silicone resin used for the first covering member 18 include a straight silicone resin and a modified silicone resin. Examples of the straight silicone resin include a methyl silicone and a methylphenyl silicone resin. Examples of the modified silicone resin include an alkyd-modified silicone resin, a polyether silicone resin, an epoxy-modified silicone resin, an acrylic-modified silicone resin, a polyester-modified silicone resin, an amino-modified silicone resin, and a carboxy-modified silicone resin. These may be used alone or in combination of two or more.

The refractive index of the silicone resin used for the first covering member 18 is not particularly limited as long as it is 1.45 or less, but is preferably 1.41 or more. The refractive index of the silicone resin can be measured by a prism coupler refractometer.

The silicone resin is a powder when the powder composition is located on the substrate 11 and between the lateral surfaces 12c of the plurality of light-emitting elements 12 in the manufacturing process of the light-emitting device, but melts when heated and cures when further heated to become a solid resin rather than a powder, as described in the item (Applying Powder Composition) to be described below. The silicone resin in the first covering member 18 in the light-emitting device 100 is a solid after curing. Because the silicone resin melted by heating has a high viscosity, the reflective member can be uniformly dispersed without being precipitated. Accordingly, the first covering member 18 includes the reflective member uniformly dispersed in the silicone resin.

The content of the reflective member in the first covering member 18 is not particularly limited, but the lower limit value of the content is preferably 50 volume % or more, more preferably 70 volume % or more. When the content of the reflective member in the first covering member 18 is 50 volume % or more, the reflectance of the light-emitting device 100 is improved. The upper limit value of the content of the reflective member in the first covering member 18 is also not particularly limited, but is preferably 85 volume % or less, more preferably 80 volume % or less. When the content of the reflective member in the first covering member 18 is 85 volume % or less, the reflective member is suitably located between the lateral surfaces 12c of the plurality of light-emitting elements 12. The lower limit value and the upper limit value of the content of the reflective member in the first covering member 18 can be appropriately combined, and the combined value is preferably in a range from 50 volume % to 85 volume %, more preferably in a range from 70 volume % to 80 volume %.

The content of the reflective member in the first covering member 18 can be measured by image analysis based on an electron micrograph.

The density of the reflective member in the first covering member 18 is 2.0 g/cm³ or more, preferably 2.5 g/cm³ or more. When the density of the reflective members in the first covering member 18 is 2.0 g/cm³ or more, a light-emitting device with high luminance and excellent contrast can be obtained. The density of the reflective member in the first covering member 18 can be measured by an underwater displacement densitometer.

The reflectance of the first covering member 18 with respect to light at the emission peak of the light-emitting element 12 is 70% or more, and is preferably 50% or more. When the reflectance of the first covering member 18 with respect to the light at the emission peak of the light-emitting element 12 is 70% or more, a light-emitting device with high luminance and excellent contrast can be obtained. The reflectance of the first covering member 18 with respect to the light at the emission peak of the light-emitting element 12 can be measured by a spectrophotometer.

The upper surface 18a of the first covering member 18 preferably has polishing or grinding marks. This is because S105 of performing the polishing or grinding to be described below is performed in the method for manufacturing the light-emitting device according to the embodiment. However, the polishing or grinding marks on the upper surface of the first covering member 18 are very fine and do not affect the luminance or contrast of the light-emitting device 100.

### Wavelength Conversion Member

The wavelength conversion member 14 is in contact with the first surface 12a of the light-emitting element 12. The wavelength conversion member 14 absorbs at least a part of light emitted from the first surface 12a of the light-emitting element 12, and emits light with a converted wavelength of the absorbed light. Note that the light-emitting device 100 according to the embodiment may not include the wavelength conversion member 14.

The wavelength conversion member 14 is preferably a plate-like member. Specifically, the wavelength conversion member 14 has, for example, a second surface (hereinafter, may be referred to as a “lower surface of the wavelength conversion member 14”) in contact with the first surface 12a of the light-emitting element 12 or on the side on which the first surface 12a of the light-emitting element 12 is disposed, a first surface (hereinafter, may be referred to as an “upper surface of the wavelength conversion member 14”) opposite to the second surface of the wavelength conversion member 14, and a lateral surface (hereinafter, may be referred to as a “lateral surface of the wavelength conversion member 14”) connecting the first surface of the wavelength conversion member 14 and the second surface of the wavelength conversion member 14. The upper surface of the wavelength conversion member 14 corresponds to the light extraction surface of the light-emitting device 100. The lower surface of the wavelength conversion member 14 is in contact with the first surface 12a of the light-emitting element 12. The lower surface of the wavelength conversion member 14 and the first surface 12a of the light-emitting element 12 are preferably bonded to each other.

The upper surface of the wavelength conversion member 14 and the lower surface of the wavelength conversion member 14 are preferably flat, and are more preferably parallel with each other. The lateral surface of the wavelength conversion member 14 may be a vertical surface perpendicular to the upper surface of the wavelength conversion member 14 and/or the lower surface of the wavelength conversion member 14, or may have an inclined surface inclined with respect to the upper surface of the wavelength conversion member 14 and/or the lower surface of the wavelength conversion member 14. The wavelength conversion member 14 may also have a step between the upper surface of the wavelength conversion member 14 and the lower surface of the wavelength conversion member 14.

The lower surface of the wavelength conversion member 14 preferably has an area in a range from about 0.8 times to about 1.5 times an area of the first surface 12a of the light-emitting element 12. The outer edge of the lower surface of the wavelength conversion member 14 may coincide with the outer edge of the first surface 12a of the light-emitting element 12, but is preferably located inside or outside the outer edge of the first surface 12a of the light-emitting element 12. That is, in a plan view, one of the outer edge of the first surface 12a of the light-emitting element 12 and the outer edge of the lower surface of the wavelength conversion member 14 is preferably included in the other.

The thickness of the wavelength conversion member 14 can be, for example, in a range from 50 μm to 300 μm. The wavelength conversion member 14 may be obtained by sintering, bonding, or adhering phosphor particles, may be obtained by dispersing and solidifying a phosphor in a resin, ceramics, or the like, or may be obtained by fixing phosphor particles on a surface of a light-transmissive plate material such as a glass plate or a ceramic plate by screen printing, discharge, or the like.

Examples of the wavelength conversion member 14 include a phosphor. As the phosphor, one known in the art can be used, and one excitable by light emitted from the light-emitting element 12 is preferably used. Examples of a phosphor that emits green light include an yttrium-aluminum-garnet-based phosphor (for example, Y₃(Al,Ga)₅O₁₂:Ce), a lutetium-aluminum-garnet-based phosphor (for example, Lu₃(Al,Ga)₅O₁₂:Ce), a terbium-aluminum-garnet-based phosphor (for example, Tb₃(Al,Ga)₅O₁₂:Ce)-based phosphor, a silicate-based phosphor (for example, (Ba,Sr)₂SiO₄:Eu), a chlorosilicate-based phosphor (for example, Ca₈Mg(SiO₄)₄C₁₂:Eu), a β-sialon-based phosphor (for example, Si_{6-z}Al_{z}O_{z}N_{8-z}:Eu (0<z<4.2)), and an SGS-based phosphor (for example, SrGa₂S₄:Eu). Examples of a phosphor that emits yellow light include an α-sialon-based phosphor (for example, M_{z}(Si,Al)₁₂(O,N)₁₆ (where 0<z≤2, and M is Li, Mg, Ca, Y, or a lanthanide element excluding La and Ce). In addition, the above phosphors that emit green light include a phosphor that emits yellow light.

For example, when Y is partially substituted with Gd in the yttrium-aluminum-garnet-based phosphor, a light emission peak wavelength can be shifted to a long wavelength side, and thus, the yttrium-aluminum-garnet-based phosphor can emit yellow light. The above phosphors include a phosphor that can emit orange light. Examples of a phosphor that emits red light include a nitrogen-containing calcium aluminosilicate (CASN or SCASN)-based phosphor (for example, (Sr,Ca)AlSiN₃:Eu) and a BSESN-based phosphor (for example, (Ba,Sr,Ca)₂Si₅N₈:Eu). Other examples include a manganese-activated fluoride-based phosphor (a phosphor represented by a general formula (I) A₂[M₁₋ₐMnₐF₆] (where, in the general formula (I), A is at least one element selected from the group consisting of K, Li, Na, Rb, Cs, and NH₄, M is at least one element selected from the group consisting of Group 4 elements and Group 14 elements, and a satisfies 0<a<0.2)). A typical example of the manganese-activated fluoride-based phosphor includes a manganese-activated potassium fluorosilicate phosphor (for example, K₂SiF₆:Mn).

When these phosphors are combined with a blue light-emitting element or an ultraviolet light-emitting element, a light-emitting device of a desired light emission color (for example, a white light-emitting device) can be manufactured.

### Protective Element

As illustrated in FIG. 1A, the protective element 25 is mounted on the upper surface of the substrate 11 to be spaced apart from the light-emitting element 12 in the first direction. The distance between the light-emitting element 12 and the protective element 25 is, for example, in a range from 0.1 times to 0.5 times one side of the light-emitting element 12 along the second direction orthogonal to the first direction. Moreover, the protective element 25 is preferably disposed in the first direction substantially at the center of the row of the plurality of light-emitting elements 12 arranged in the first direction. Note that the light-emitting device 100 according to the first embodiment may not include the protective element 25.

Examples of the protective element 25 include capacitors, varistors, Zener diodes, and bridge diodes.

As illustrated in FIGS. 1A, the protective element 25 is preferably disposed so that the lateral surface of the protective element 25 faces the lateral surface 12c of the light-emitting element 12. Thus, the lateral surface of the protective element 25 and the lateral surface 12c of the light-emitting element 12 can be disposed close to each other with a constant distance therebetween, the protective element 25 facing the light-emitting element 12.

A planar shape of the protective element 25 is, for example, substantially rectangular. The vertical, horizontal, and height dimensions of the protective element can be set arbitrarily. Among these, from the viewpoint of downsizing of the light-emitting device, the vertical and horizontal dimensions of the protective element are preferably smaller than the vertical and horizontal dimensions of the light-emitting element 12 in a plan view. The height of the protective element is preferably lower than the total height of the light-emitting element and the light-transmissive member.

### Frame Body

The frame body 150 is a member that is disposed on the substrate 11, surrounds the plurality of light-emitting elements 12, and supports the first covering member 18. The light-emitting device 100 according to the embodiment may not include the frame body 150, but preferably includes the frame body 150 to fill the entire light-emitting device 100 with the first covering member 18.

As illustrated in FIGS. 1A and 1, preferably, the frame body 150 is disposed on the substrate 11 to surround the plurality of light-emitting elements 12, and surrounds the plurality of light-emitting elements 12 to which the wavelength conversion member 14 is bonded and the protective elements 25 to be spaced apart from the wavelength conversion member 14, the light-emitting elements 12, and the protective elements 25. As illustrated in FIG. 1A, the frame body 150 has a substantially rectangular annular structure in a plan view. In this case, the rectangular shape may be a rounded rectangular shape, and at least a part of a connecting portion may be a so-called round shape.

Examples of the material of the frame body 150 include metals, alloys, ceramics, and resins. Examples of the metal include Fe, Cu, Ni, Al, Ag, Au, Al, Pt, Ti, W, and Pd. Examples of the alloy include an alloy containing at least one selected from the group consisting of Fe, Cu, Ni, Al, Ag, Au, Al, Pt, Ti, W, and Pd.

Examples of the resin as the material of the frame body 150 include an insulating resin. Any one of a thermosetting resin and a thermoplastic resin may be used as the insulating resin. Specific examples of the resin include epoxy resins, silicone resins, modified epoxy resins, modified silicone resins, polyester resins, polyimide resins, modified polyimide resins, polyphthalamide (PPA), polycarbonate resins, polyphenylene sulfide (PPS), liquid crystal polymer (LCP), ABS resins, phenol resins, acrylic resins, and PBT resins. These may be used alone or in combination of two or more. Among these, a thermosetting resin such as an epoxy resin or a silicone resin, which has excellent heat resistance and light resistance, is preferably used. The resin of the frame body 150 may be a light-transmissive resin.

A metal, an alloy, or ceramics may be embedded in the frame body 150 made of a resin, or a part of the frame body 150 may be made of a resin and another part thereof may be made of a metal, an alloy, or ceramics.

The material of the frame body 150 may be a mixture containing a resin and a light reflective material. As the light reflective material, a member that does not easily absorb light from the light-emitting element and has a great refractive index difference with respect to a resin is preferably used. Examples of such a light reflective material include titanium oxide, zinc oxide, silicon oxide, zirconium oxide, yttrium oxide, yttria-stabilized zirconia, potassium titanate, aluminum oxide, aluminum nitride, boron nitride, and mullite. These light reflective materials can be contained in a range from 5 mass % to 90 mass % with respect to a resin. The viscosity of a mixture of the resin and the light reflective material for forming the frame body 150 is not particularly limited, but is preferably in a range from 200 Pa s to 800 Pa s, more preferably in a range from 350 Pa s to 450 Pa s.

The material of the frame body 150 may be a mixture containing a resin and a light absorbing material such as carbon black or graphite.

The light-emitting device according to the first embodiment described above can be suitably manufactured by a method for manufacturing a light-emitting device according to the first embodiment to be described below.

### Light-Emitting Device According to Second Embodiment

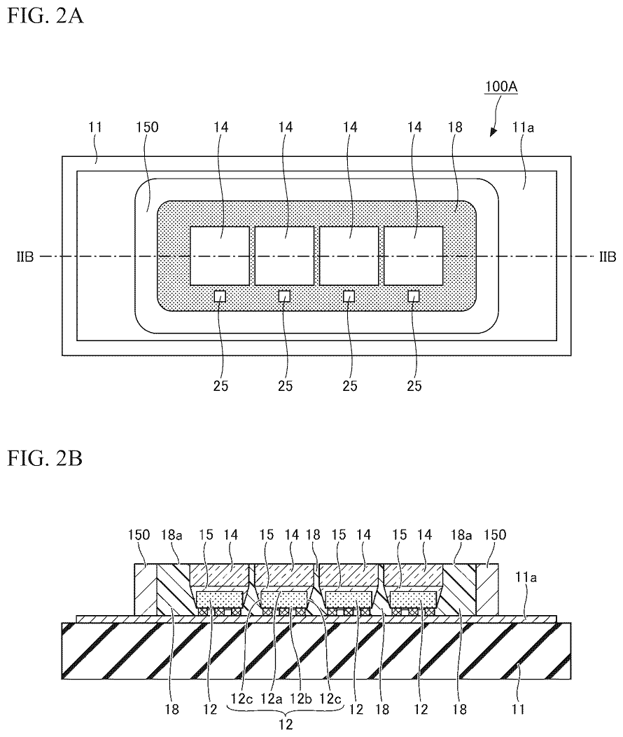

FIG. 2A is a schematic plan view illustrating an example of a light-emitting device according to a second embodiment. FIG. 2B is a schematic cross-sectional view taken along line IIB-IIB in FIG. 2A.

As illustrated in FIGS. 2A and 2B, a light-emitting device 100A according to the second embodiment includes the substrate 11, the light-emitting element 12, the first covering member 18, the wavelength conversion member 14, the light-transmissive member 15, the protective elements 25, and the frame body 150.

The light-emitting device 100A according to the second embodiment is the same as the light-emitting device 100 according to the first embodiment except that the wavelength conversion member 14 is disposed above the first surface 12a of the light-emitting element 12 and the light-transmissive member 15 is provided. The wavelength conversion member 14 and the light-transmissive member 15 of the light-emitting device 100A are described below.

### Wavelength Conversion Member

The wavelength conversion member 14 is the same as in the light-emitting device 100 according to the first embodiment except that the wavelength conversion member 14 is disposed above the first surface 12a of the light-emitting element 12.

The wavelength conversion member 14 being disposed above the first surface 12a of the light-emitting element 12 means that another member such as an adhesive may be disposed between the first surface 12a of the light-emitting element 12 and the lower surface of the wavelength conversion member 14. In other words, the lower surface of the wavelength conversion member 14 is disposed above the first surface 12a of the light-emitting element 12 to face the first surface 12a of the light-emitting element 12. Examples of another member include the light-transmissive member 15 such as an adhesive, a glass plate, or a ceramic plate.

When one light-emitting element 12 is disposed with respect to one wavelength conversion member 14, the area of the lower surface of the wavelength conversion member 14 is preferably the same as the area of the upper surface of the light-transmissive member 15, but can also be in a range from about 0.8 times to about 1.5 times. When two or more light-emitting elements 12 are disposed with respect to one wavelength conversion member 14, the light-transmissive member 15 may cover the entire lower surface of the wavelength conversion member 14. The outer edge of the lower surface of the wavelength conversion member 14 preferably matches with the outer edge of the upper surface of the light-transmissive member 15, but may be located inside or outside the outer edge of the upper surface of the light-transmissive member 15. That is, in a plan view, one of the outer edge of the upper surface of the light-transmissive member 15 and the outer edge of the lower surface of the wavelength conversion member 14 is preferably included in the other.

### Light-Transmissive Member

The light-transmissive member 15 is a member that transmits light emitted from the light-emitting element 12 and discharges the light to the outside. Examples of the light-transmissive member 15 include a member that transmits 60% or greater of light from the light-emitting element 12 (for example, light with a wavelength in a range from 320 nm to 850 nm), and preferably include a member that transmits 70% or greater of the light. The light-transmissive member 15 preferably bonds the lower surface of the wavelength conversion member 14 to the first surface 12a of the light-emitting element 12. Note that the light-emitting device 100 according to the first embodiment may not include the light-transmissive member 15.

For example, when the light-transmissive member 15 is a glass plate or a ceramic plate, the light-transmissive member 15 has a second surface (hereinafter, may be referred to as “lower surface of the light-transmissive member 15”) bonded to the first surface 12a of the light-emitting element 12, a first surface (hereinafter, may be referred to as “upper surface of the light-transmissive member 15”) opposite to the first surface of the light-transmissive member 15 and bonded to the lower surface of the wavelength conversion member 14, and a lateral surface (hereinafter, may be referred to as “lateral surface of the light-transmissive member 15”) connecting the first surface of the light-transmissive member 15 and the second surface of the light-transmissive member 15. The upper surface of the light-transmissive member 15 and the lower surface of the light-transmissive member 15 are preferably flat, and are more preferably parallel with each other. The lateral surface of the light-transmissive member 15 may be a vertical surface perpendicular to the upper surface of the light-transmissive member 15 and/or the lower surface of the light-transmissive member 15, or may have an inclined surface inclined with respect to the upper surface of the light-transmissive member 15 and/or the lower surface of the light-transmissive member 15. The light-transmissive member 15 may have a step between the upper surface and the lower surface thereof.

When the light-transmissive member 15 is an adhesive, the light-transmissive member 15 may be disposed on the first surfaces 12a and the lateral surfaces of the light-emitting elements 12, or the surface of the light-transmissive member 15 may have irregularities. For example, the light-transmissive member 15 may rise above the lateral surface of the light-emitting element 12.

The thickness of the light-transmissive member 15 can be, for example, in a range from 5 μm to 300 μm, but is preferably in a range from 10 μm to 200 μm, more preferably in a range from 15 μm to 100 μm.

The light-transmissive member 15 can be formed from an inorganic material such as glass, ceramics, or sapphire, or an organic material such as a resin or a hybrid resin containing one or more of silicone resins, modified silicone resins, epoxy resins, modified epoxy resins, acrylic resins, phenol resins, and fluorine resins.

The light-transmissive member 15 may contain a light-diffusing material. As the light-diffusing material, any of those commonly used in the art such as fillers of titanium oxide, barium titanate, aluminum oxide, silicon oxide, zirconium oxide, aerosil, glass, glass fiber, or wollastonite, aluminum nitride, or the like may be used.

The light-transmissive member 15 may also contain the wavelength conversion member 14. Whether the light-transmissive member 15 or the wavelength conversion member 14 is to be formed is determined by using the name of the light-transmissive member 15 or the wavelength conversion member 14 having the larger total weight of the members contained therein. Examples of the light-transmissive member containing the wavelength conversion member 14 include a sintered compact of a phosphor, a resin, glass, ceramics, or another inorganic material, which contains phosphor. A resin layer containing a phosphor may be formed on the surface of a molded body of resin, glass, ceramics, or the like.

The light-emitting device according to the second embodiment described above can be suitably manufactured by the method for manufacturing the light-emitting device according to the first embodiment to be described below.

### Light-Emitting Device According to Third Embodiment

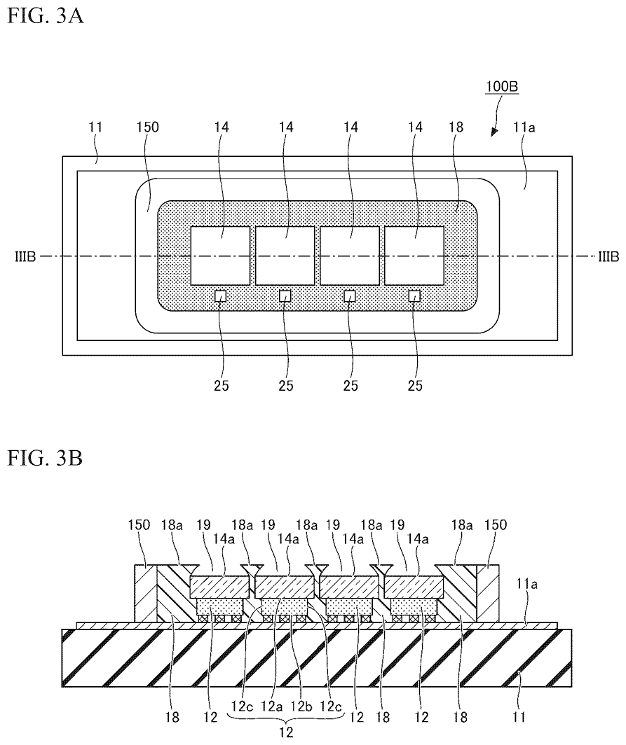

FIG. 3A is a schematic plan view illustrating an example of a light-emitting device according to a third embodiment. FIG. 3B is a schematic cross-sectional view taken along line IIIB-IIIB in FIG. 3A.

A light-emitting device 100B according to the third embodiment is the same as the light-emitting device 100 according to the first embodiment except that the shape of the upper surface 18a of the first covering member 18 is different. The first covering member 18 of the light-emitting device 100B is described below.

### First Covering Member

The first covering member 18 is provided on the substrate 11 and between the lateral surfaces 12c of the plurality of light-emitting elements 12. As illustrated in FIG. 3B, the upper surface 18a of the first covering member 18 is higher than the first surface 12a of the light-emitting element 12 or the upper surface 14a of the wavelength conversion member 14 and has a recessed portion 19, and an inner bottom of the recessed portion 19 is the first surface 12a of the light-emitting element 12 or the upper surface 14a of the wavelength conversion member 14. FIG. 3B illustrates an example in which the inner bottom of the recessed portion 19 is the upper surface 14a of the wavelength conversion member 14.

The inner bottom of the recessed portion 19 of the first covering member 18 preferably has an area in a range from about 0.9 times to about 1 time the area of the first surface 12a of the light-emitting element 12 or the upper surface 14a of the wavelength conversion member 14. The outer edge of the inner bottom of the recessed portion 19 of the first covering member 18 may coincide with the outer edge of the first surface 12a of the light-emitting element 12 or the outer edge of the upper surface 14a of the wavelength conversion member 14, or may be located inside or outside the outer edge of the first surface 12a of the light-emitting element 12 or the outer edge of the upper surface 14a of the wavelength conversion member 14. That is, in a plan view, one of the outer edge of the inner bottom of the recessed portion 19 of the first covering member 18 and the outer edge of the first surface 12a of the light-emitting element 12 or the outer edge of the upper surface 14a of the wavelength conversion member 14 may be included in the other.

An opening of the recessed portion 19 of the first covering member 18 preferably has an area in a range from about 0.9 times to about 1 time the area of the first surface 12a of the light-emitting element 12 or the upper surface 14a of the wavelength conversion member 14. The outer edge of the opening of the recessed portion 19 of the first covering member 18 may coincide with the outer edge of the first surface 12a of the light-emitting element 12 or the outer edge of the upper surface 14a of the wavelength conversion member 14, or may be located inside or outside the outer edge of the first surface 12a of the light-emitting element 12 or the outer edge of the upper surface 14a of the wavelength conversion member 14; however, the outer edge of the opening of the recessed portion 19 of the first covering member 18 is located inside the outer edge of the first surface 12a of the light-emitting element 12 or the outer edge of the upper surface 14a of the wavelength conversion member 14. That is, in a plan view, the outer edge of the opening of the recessed portion 19 of the first covering member 18 is preferably included in the outer edge of the first surface 12a of the light-emitting element 12 or the outer edge of the upper surface 14a of the wavelength conversion member 14. Such a configuration can obtain a light-emitting device that can reduce the spread of light emitted from the light-emitting element 12 in a direction perpendicular to the thickness direction of the substrate 11 (the same direction as the surface direction of the first surface 12a of the light-emitting element 12) and increase the amount of light traveling straight in the thickness direction of the substrate 11 (direction perpendicular to the first surface 12a of the light-emitting element 12), and has higher luminance and more excellent contrast.

The light-emitting device according to the third embodiment described above can be suitably manufactured by a method for manufacturing a light-emitting device according to the second embodiment or a method for manufacturing a light-emitting device according to the third embodiment that is to be described below.

### Method for Manufacturing Light-Emitting Device

A method for manufacturing a light-emitting device according to an embodiment includes: preparing an intermediate body in which a plurality of light-emitting elements each having a first surface serving as a light extraction surface, a second surface opposite to the first surface, and a lateral surface connecting the first surface and the second surface are disposed on a substrate; applying a powder composition including a reflective member and a silicone resin powder from above the first surfaces of the plurality of light-emitting elements through a sieve to located the powder composition on the substrate and between the lateral surfaces of the plurality of light-emitting elements; and forming a first covering member by applying vibration to the powder composition and then applying pressure in a thickness direction of the substrate to perform compression molding, and further includes other steps as necessary.

Method for Manufacturing Light-emitting Device according to First Embodiment

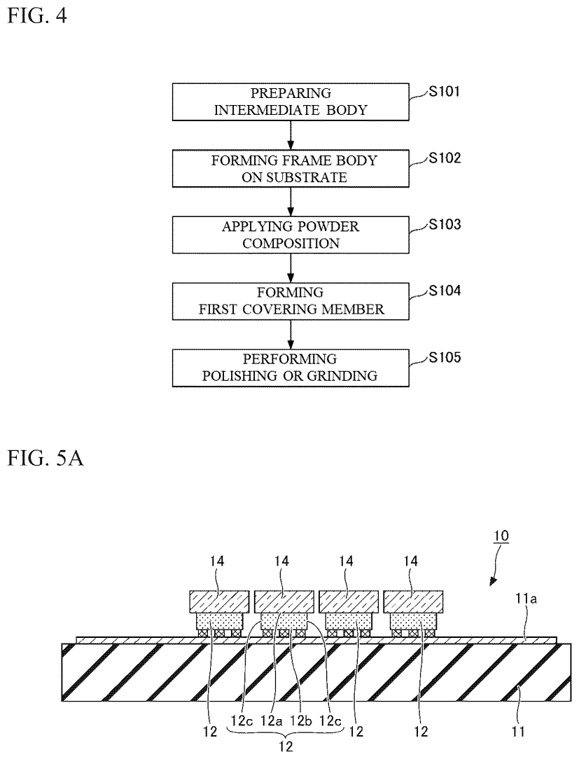

FIG. 4 is a flowchart showing an example of the method for manufacturing the light-emitting device according to the first embodiment. The method for manufacturing the light-emitting device according to the first embodiment includes S101 of preparing an intermediate body, S103 of applying a powder composition, and S104 of forming a first covering member. In addition to the steps described above, the method preferably further includes S102 of forming a frame body on a substrate and S105 of performing polishing or grinding. An example of the method for manufacturing the light-emitting device according to the first embodiment is described below.

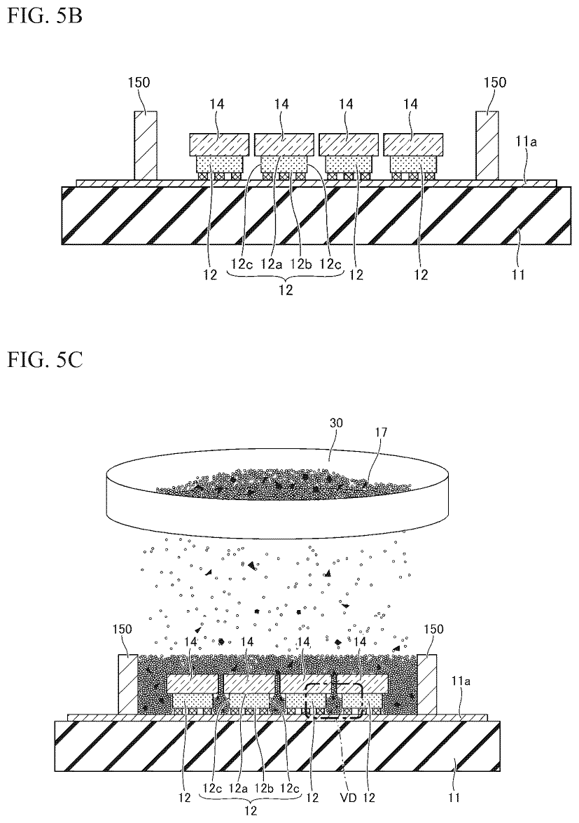

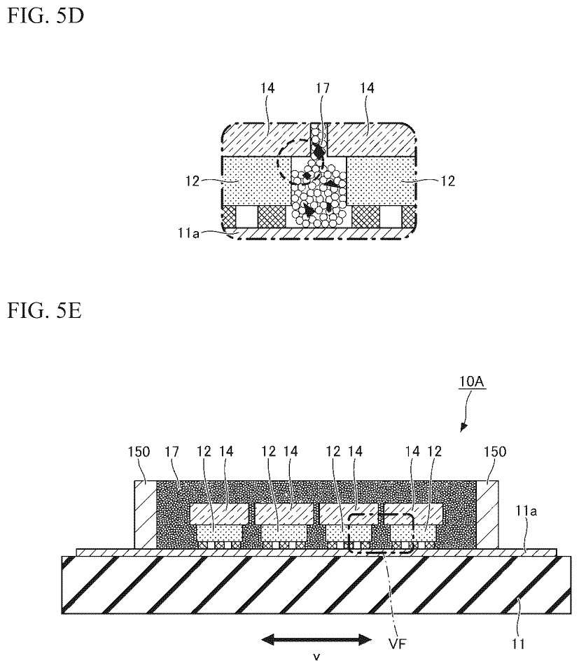

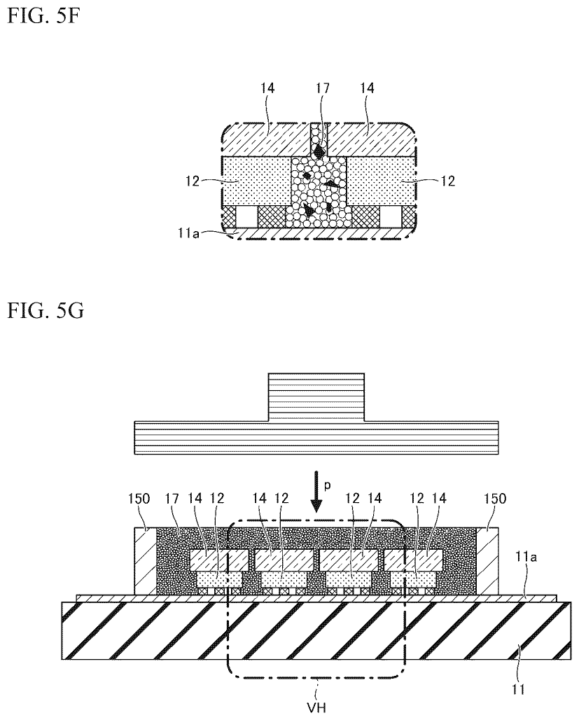

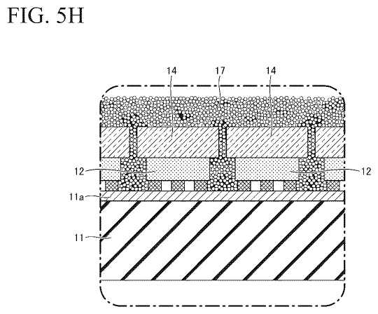

FIG. 5A is a schematic cross-sectional view illustrating S101 of preparing the intermediate body in the method for manufacturing the light-emitting device according to the first embodiment. FIG. 5B is a schematic cross-sectional view illustrating the forming of the frame body on the substrate in the method for manufacturing the light-emitting device according to the first embodiment. FIG. 5C is a schematic cross-sectional view illustrating the applying of the powder composition in the method for manufacturing the light-emitting device according to the first embodiment. FIG. 5D is a schematic enlarged cross-sectional view of a region VD in FIG. 5C. FIG. 5E is a schematic cross-sectional view illustrating the forming of the first covering member in the method for manufacturing the light-emitting device according to the first embodiment. FIG. 5F is a schematic enlarged cross-sectional view of a region VF in FIG. 5E. FIG. 5G is a schematic cross-sectional view illustrating an example of compression-molding of the powder composition in the forming of the first covering member in the method for manufacturing the light-emitting device according to the first embodiment. FIG. 5H is a schematic enlarged cross-sectional view of a region VH in FIG. 5E.

### S101. Preparing Intermediate Body

As illustrated in FIG. 5A, in S101 of preparing the intermediate body, an intermediate body 10 is prepared in which the plurality of light-emitting elements 12 each having the first surface 12a serving as a light extraction surface, the second surface 12b opposite to the first surface 12a, and the lateral surface 12c connecting the first surface 12a and the second surface 12b are disposed on the substrate 11. In the method for manufacturing the light-emitting device according to the embodiment, “preparing” a member is not limited to manufacturing the member, and includes acquiring the member such as purchasing the member or receiving the member.

The light-emitting element 12 is mounted on the substrate 11 such that the second surface 12b provided with the electrodes faces the substrate 11 as a lower surface. Specifically, the first electrode or the second electrode of the light-emitting element 12 is connected to the wiring line 11a provided on the substrate 11 via a bonding member. As the bonding member, those described in the above item <Light-emitting Element> can be used.

S101 of preparing the intermediate body may further include disposing the wavelength conversion member 14 in contact with the first surface 12a of the light-emitting element 12 or above the first surface 12a of the light-emitting element 12.

When the wavelength conversion member 14 is in contact with the first surface 12a of the light-emitting element 12 in S101 of preparing the intermediate body, the intermediate body 10 includes the substrate 11, the plurality of light-emitting elements 12 arranged on the upper surface of the substrate 11 in the first direction, and the wavelength conversion member 14 bonded to the first surface 12a being the upper surface of each of the light-emitting elements 12, as illustrated in FIG. 5A.

When the wavelength conversion member 14 is in contact with the first surface 12a of the light-emitting element 12, the lower surface of the wavelength conversion member 14 and the first surface 12a of the light-emitting element 12 can be bonded to each other using a light-transmissive adhesive or the like that is commonly used in the art. The lower surface of the wavelength conversion member 14 and the first surface 12a of the light-emitting element 12 may be bonded to each other by a direct bonding method using pressure bonding, surface activation bonding, atomic diffusion bonding, or hydroxyl group bonding.

When the wavelength conversion member 14 is disposed above the first surface 12a of the light-emitting element 12 in S101 of preparing the intermediate body, for example, the light-transmissive member 15 is disposed between the light-emitting element 12 and the wavelength conversion member 14, and specifically, as illustrated in FIG. 2B, the intermediate body 10 includes the substrate 11, the plurality of light-emitting elements 12 arranged on the upper surface of the substrate 11 in the first direction, the light-transmissive member 15 bonded to the first surface 12a being the upper surface of each of the light-emitting elements 12, and the wavelength conversion member 14 bonded to the upper surface of each of the light-transmissive members 15.

When the light-transmissive member 15 is in contact with the lower surface of the wavelength conversion member 14, the upper surface of the light-transmissive member 15 and the lower surface of the wavelength conversion member 14 can be bonded to each other using a light-transmissive adhesive or the like that is commonly used in the art.

S101 of preparing the intermediate body may further include disposing the protective element 25 on the upper surface of the substrate 11 to be spaced apart from and to face the light-emitting element 12 in the second direction orthogonal to the first direction.

### S102: Forming Frame Body on Substrate

As illustrated in FIG. 5B, S102 of forming the frame body on the substrate is preferably performed before S104 of forming the first covering member. In S102 of forming the frame body on the substrate, the frame body 150 surrounding the plurality of light-emitting elements 12 is formed on the substrate 11 before applying the powder composition. For example, when the plurality of light-emitting elements 12 are disposed in a line in the first direction on the substrate 11 having a rectangular shape in a plan view, the frame body 150 preferably has a substantially rectangular frame shape surrounding the plurality of light-emitting elements 12. S102 of forming the frame body on the substrate may be performed before, after, or simultaneously with S101 of preparing the intermediate body.

In the frame body 150, all sides may have the same height and the same width, or some or all sides may have different heights and/or different widths.

The height of the frame body 150 from the upper surface of the substrate 11 is preferably higher than the first surface 12a of the light-emitting element 12 as illustrated in FIG. 5B, for example. The height from the upper surface of the substrate 11 to the top of the frame body 150 may be lower than the height from the upper surface of the substrate 11 to the upper surface of the wavelength conversion member 14, but is preferably higher than the height from the upper surface of the substrate 11 to the upper surface of the wavelength conversion member 14. For example, when the height from the upper surface of the substrate 11 to the upper surface of the wavelength conversion member 14 is 350 μm, the height of the frame body 150 is in a range from 150 μm to 400 μm. Thus, in S103 of applying the powder composition, the powder composition can be suitably applied onto the first surfaces 12a of the plurality of light-emitting elements 12 and between the lateral surfaces 12c of the plurality of light-emitting elements 12.

The width of the frame body 150 (that is, the length of the bottom side of the frame body 150 in a direction orthogonal to a direction in which the frame body 150 extends) can be appropriately set depending on the height, the material to be used, and the like as long as the frame body 150 has strength enough to stand by itself. The width of the frame body 150 is, for example, in a range from 200 μm to 600 μm.

The frame body 150 can be formed, for example, using a device known in the art, such as a discharge device (resin discharge device) that can discharge a liquid resin with air pressure or the like at continuous and constant discharge flow rate (see JP 2009-182307 A). When the discharge device is used, the frame body 150 having a desired height and width can be formed by adjusting the moving speed of a needle of the discharge device and the discharge flow rate thereof.

### S103: Applying Powder Composition

As illustrated in FIG. 5C, in S103 of applying the powder composition, a powder composition 17 containing a reflective member and a silicone resin powder is applied from above the first surfaces 12a of the plurality of light-emitting elements 12 through a sieve 30, and is located on the substrate 11 and between the lateral surfaces 12c of the plurality of light-emitting elements 12. When the light-emitting device 100 includes the frame body 150, the powder composition 17 is preferably further located between the lateral surface of the frame body 150 on which the light-emitting elements 12 are disposed and the lateral surfaces 12c of the light-emitting elements 12.

Applying the powder composition 17 through the sieve 30 is performed for the purpose of removing aggregation of the powder composition 17 and uniformly applying and locating the powder composition 17 on the substrate 11 and between the lateral surfaces 12c of the plurality of light-emitting elements 12. Therefore, the dimensions (width and depth), shape, structure, and mesh size of the sieve 30 are not particularly limited and can be appropriately selected depending on the dimensions of the light-emitting device 100, the particle diameter of the powder composition 17 to be used, and the like. The dimension (width) of the sieve 30 is preferably such that the sieve 30 can cover all of the plurality of light-emitting elements 12 in the light-emitting device 100 because the powder composition 17 can be uniformly applied and located on the substrate 11 and between the lateral surfaces 12c of the plurality of light-emitting elements 12 by a single operation. As the sieve 30, for example, when the powder composition 17 contains a reflective member having a particle diameter in a range from 0.05 μm to 1 μm and a silicone resin powder having a particle diameter in a range from 1 μm to 150 μm, a 100 μm standard sieve (100 mesh) can be used. The width, speed, and time for sieving the sieve 30 are also not particularly limited. The sieve 30 may be operated manually or using a known device (such as a sieving machine). Alternatively, instead of the sieve 30 or in addition to the sieve 30, a brush or a squeegee may be used to apply the powder composition 17 between the lateral surfaces 12c of the plurality of light-emitting elements 12.

In S103 of applying the powder composition, the powder composition 17 may be located on the substrate 11 and between the lateral surfaces 12c of the plurality of light-emitting elements 12; however, preferably, the powder composition 17 is further applied onto the first surfaces 12a of the plurality of light-emitting elements 12 and between the lateral surfaces 12c of the plurality of light-emitting elements 12. Thus, the upper surface 18a of the first covering member 18 and the first surface 12a of the light-emitting element 12 can be made flush with each other in S105 of performing the polishing or grinding to be described below.

Specifically, in S103 of applying the powder composition, as illustrated in FIG. 5D, voids of the powder composition 17 located between the lateral surfaces 12c of the plurality of light-emitting elements 12 may be formed in gaps or the like corresponding to the thickness of a bonding member between the powder compositions 17, between the powder composition 17 and the lateral surfaces 12c of the light-emitting elements 12, and between the second surface 12b of the light-emitting element 12 and the substrate 11 due to the fluidity of the powder composition 17 or the structure of the light-emitting device 100. The voids are removed in S104 of forming the first covering member to be described below; however, in a case in which the powder composition 17 is applied onto the substrate 11 and only between the lateral surfaces 12c of the plurality of light-emitting elements 12 (the lateral surfaces 12c of the light-emitting elements 12), when the powder composition 17 is compression-molded in S104 of forming the first covering member, the powder composition 17 is compressed toward the substrate 11, the upper surface (exposed surface) of the powder composition 17 located between the lateral surfaces 12c of the light-emitting elements 12 is not flush with the first surface 12a of the light-emitting elements 12, and finally the upper surface 18a of the first covering member 18 becomes a recessed portion between the lateral surfaces 12c of the plurality of light-emitting elements 12. On the other hand, this can be prevented by applying the powder composition 17 to cover the first surface 12a of the light-emitting element 12 in S103 of applying the powder composition.

In addition, when the silicone resin powder in the powder composition 17 is a condensation type silicone resin powder, the volume may shrink due to condensation after curing; however, by applying the powder composition 17 onto the first surfaces 12a of the plurality of light-emitting elements 12 and between the lateral surfaces 12c of the plurality of light-emitting elements 12, the upper surface 18a (exposed surface) of the first covering member 18 formed from the powder composition 17 located between the lateral surfaces 12c of the light-emitting elements 12 can be made flush with the first surfaces 12a of the light-emitting elements 12 even though the condensation type silicone resin powder shrinks.

### Powder Composition

The powder composition 17 contains the reflective member and the silicone resin powder, and further contains other components as necessary.

The reflective member is as described in <First Covering Member>. The particle diameter of the reflective member is not particularly limited as long as the reflective member can be located between the lateral surfaces 12c of the plurality of light-emitting elements 12, but is preferably in a range from 0.05 μm to 1 μm. When the particle diameter of the reflective member is 1 μm or less, the gap between the reflective members is reduced, so that contrast and luminance are improved. From the viewpoint of efficiently scattering a blue wavelength to a yellow wavelength, the particle diameter of the reflective member is more preferably in a range from 0.15 μm to 0.35 μm. As the reflective member, a reflective member having a sharp particle size distribution is preferably used, and a reflective member having a single particle size is more preferably used in terms of closest packing between the lateral surfaces 12c of the plurality of light-emitting elements 12; however, a reflective member having various particle diameters in a range from 0.05 μm to 1 μm and a broad particle size distribution may be used.

The refractive index of the reflective member is not particularly limited, but is preferably in a range from 2.52 to 2.72 at a wavelength of 550 nm. The larger the difference in refractive index between the silicone resin powder and the reflective member, the higher the contrast and the higher the luminance. The refractive index of the reflective member can be measured by a critical angle method using a spectrophotometer.

The silicone resin powder may be an addition type silicone resin or a condensation type silicone resin. The shape of the silicone resin powder is not particularly limited, and examples thereof include a crushed shape and a spherical shape. Among these, a spherical shape is preferable in terms of high fluidity.

The particle diameter of the silicone resin powder is not particularly limited as long as it can be located between the lateral surfaces 12c of the plurality of light-emitting elements 12, but is preferably in a range from 1 μm to 150 μm. As the silicone resin powder, a silicone resin powder having various particle diameters in a range from 1 μm to 150 μm and a broad particle size distribution may be used. By using the silicone resin powder having a broad particle size distribution, the aggregation of the powder composition 17 is prevented, the fluidity is increased, and the powder composition 17 can enter without a gap even when the distance between the lateral surfaces of the plurality of light-emitting elements 12 is narrow.

The refractive index of the silicone resin powder is not particularly limited, but is preferably in a range from 1.36 to 1.43. The larger the difference in refractive index between the silicone resin powder and the reflective member, the higher the contrast and the higher the luminance. The refractive index of the silicone resin powder can be measured by a critical angle method using a spectrophotometer.

The content of the reflective member in the powder composition 17 is not particularly limited, but is preferably 50 volume % or more, more preferably 70 volume % or more. When the content of the reflective member in the powder composition 17 is 50 volume % or more, the reflectance of the light-emitting device 100 is improved. The upper limit value of the content of the reflective member in the powder composition 17 is also not particularly limited, but is preferably 85 volume % or less, more preferably 80 volume % or less. When the content of the reflective member in the powder composition 17 is 85 volume % or less, the reflective member is suitably located between the lateral surfaces 12c of the plurality of light-emitting elements 12. The lower limit value and the upper limit value of the content of the reflective member in the first covering member 18 can be appropriately combined, and is preferably in a range from 50 volume % to 85 volume %, more preferably in a range from 70 volume % to 80 volume %.

### S104: Forming First Covering Member

As illustrated in FIGS. 5E and 5G, in S104 of forming the first covering member, vibration v is applied to the powder composition 17, and then pressure p is applied in the thickness direction of the substrate 11 to compress and mold the powder composition 17, thereby forming the first covering member 18. In other words, in S104 of forming the first covering member, the vibration v is applied to the powder composition 17 applied onto the substrate 11 and between the lateral surfaces 12c of the plurality of light-emitting elements 12 in S103 of applying the powder composition, and then the powder composition 17 is compression-molded by applying the pressure p in the thickness direction of the substrate 11 to form the first covering member 18.

In S104 of forming the first covering member, by applying the vibration v to the powder composition 17, as illustrated in FIG. 5F, the voids of the powder composition 17 can be reduced in the gaps or the like corresponding to the thickness of the bonding member between the powder compositions 17, between the powder composition 17 and the lateral surfaces 12c of the light-emitting elements 12, and between the second surface 12b of the light-emitting element 12 and the substrate 11, the voids occurring in S103 of applying the powder composition.

After the vibration v is applied to the powder composition 17, the pressure p is applied to the powder composition 17 in the thickness direction of the substrate 11 for compression molding, so that the voids in the gaps or the like corresponding to the thickness of the bonding member between the powder compositions 17, between the powder composition 17 and the lateral surfaces 12c of the light-emitting elements 12, and between the second surface 12b of the light-emitting element 12 and the substrate 11, which occur in S103 of applying the powder composition, can be further filled therewith.

The method of applying the vibration v to the powder composition 17 is not particularly limited, and examples thereof include a method of applying the vibration v to an intermediate body 10A of the light-emitting device, to which the powder composition 17 has been applied, from the lower surface of the substrate 11 (surface opposite to the surface on which the light-emitting elements 12 are disposed). The applying of the vibration v to the powder composition 17 may be performed manually or using a known device (for example, a vibration applying device or the like).

The applying of the vibration v to the powder composition 17 in S104 of forming the first covering member may be performed simultaneously with S103 of applying the powder composition. For example, the vibration v may be applied to the powder composition 17 from the lower surface of the substrate 11 while the powder composition 17 is applied through a sieve from above the first surfaces 12a of the plurality of light-emitting elements 12. Alternatively, the powder composition 17 may be disposed on the first surfaces 12a of the plurality of light-emitting elements 12, and the vibration v may be applied to the powder composition 17 while the powder composition 17 is applied between the lateral surfaces 12c of the plurality of light-emitting elements 12 by using a brush or a squeegee. The method of simultaneously performing S104 of forming the first covering member and the applying of the vibration v to the powder composition 17 may be performed manually or using a known device (for example, a vibration sieve device or the like). Thus, S103 of applying the powder composition and S104 of forming the first covering member can be more efficiently performed, and gaps can be prevented from being formed in the vicinity of the upper surface 18a of the first covering member 18 at the time of compression forming.

The frequency, displacement, speed, and acceleration of the vibration v applied to the powder composition 17 are not particularly limited. The direction of the vibration v applied to the powder composition 17 is not particularly limited and may be the thickness direction of the substrate 11 (the thickness direction of the light-emitting element 12, the same direction as the surface direction of the lateral surface 12c of the light-emitting element 12, and the direction perpendicular to the surface direction of the first surface 12a and the second surface 12b of the light-emitting element 12), or the direction perpendicular to the thickness direction of the substrate 11 (the direction perpendicular to the thickness direction of the light-emitting element 12, the direction perpendicular to the surface direction of the lateral surface 12c of the light-emitting element 12, the same direction as the surface direction of the first surface 12a and the second surface 12b of the light-emitting element 12, and the direction indicated by an arrow v in FIG. 5E). Among these, the direction perpendicular to the thickness direction of the substrate 11 is preferable.

In S104 of forming the first covering member, after the vibration v is applied to the powder composition 17, as illustrated in FIG. 5G, the powder composition 17 is compression-molded by applying the pressure p in the thickness direction (p direction in FIG. 5G) of the substrate 11 to form the first covering member 18.

The method of applying the pressure p to the powder composition 17 in the thickness direction of the substrate 11 is not particularly limited, and may be performed manually or using a known device (for example, a compression molding device or the like). The compression-molding of the powder composition 17 is performed by placing the substrate 11 in the direction of gravity and placing the first surface 12a of the light-emitting device in a position opposite to the direction of gravity so that the applied powder composition 17 is not discharged from between the lateral surfaces 12c of the plurality of light-emitting elements 12.

The pressing force and the pressing time when the powder composition 17 is compression-molded are not particularly limited as long as the light-emitting device 100 and each member are not broken; however, the powder composition 17 is preferably compression-molded such that the density of the reflective member in the first covering member 18 is 2.0 g/cm³ or more, and is preferably pressed in a range from 0.02 MPa to 20 MPa for 1 minute or more. By setting the density of the reflective member in the first covering member 18 to 2.0 g/cm³ or more, a light-emitting device with high luminance and excellent contrast can be suitably obtained.

When the powder composition 17 is applied onto the first surfaces 12a of the plurality of light-emitting elements 12 and between the lateral surfaces 12c of the plurality of light-emitting elements 12 in S103 of applying the powder composition, the first covering member 18 is formed on the first surfaces 12a of the plurality of light-emitting elements 12 and between the lateral surfaces 12c of the plurality of light-emitting elements 12 in S104 of forming the first covering member.

S104 of forming the first covering member preferably includes heating the powder composition 17 to a temperature equal to or higher than the melting temperature of the silicone resin powder and equal to or lower than the curing temperature of the silicone resin powder, and curing the powder composition 17 at a temperature equal to or higher than the curing temperature of the silicone resin powder. Heating the powder composition 17 to the temperature equal to or higher than the melting temperature of the silicone resin powder and equal to or lower than the curing temperature of the silicone resin powder is preferably performed after or during the compression molding of the powder composition 17, and is more preferably performed during the compression molding. Curing the powder composition 17 at the temperature equal to or higher than the curing temperature of the silicone resin powder is preferably performed after the compression molding, and is more preferably performed after heating the powder composition 17 to the temperature equal to or higher than the melting temperature of the silicone resin powder and equal to or lower than the curing temperature of the silicone resin powder.

In S104 of forming the first covering member, by heating the silicone resin powder to the temperature equal to or higher than the melting temperature of the silicone resin powder and equal to or lower than the curing temperature of the silicone resin powder, the silicone resin powder is melted, and as illustrated in FIG. 5H, the melted silicone resin spreads into the voids in the gaps or the like corresponding to the thickness of the bonding member between the powder compositions 17, between the powder composition 17 and the lateral surfaces 12c of the light-emitting elements 12, and between the second surface 12b of the light-emitting element 12 and the substrate 11, so that the voids can be eliminated. In particular, the melted silicone resin can efficiently fill the gap between the reflective members.

Subsequently, in S104 of forming the first covering member, the melted silicone resin is heated at the temperature equal to or higher than the curing temperature of the silicone resin powder, thereby forming the first covering member 18 in which the melted silicone resin has been cured.

### S105: Performing Polishing or Grinding

After S104 of forming the first covering member, at least one of the first covering member 18 or the first surface 12a of the light-emitting element 12 is preferably polished or ground (S105) so that the upper surface 18a of the first covering member 18 and the first surface 12a of the light-emitting element 12 are flush with each other. In particular, when the powder composition 17 includes a condensation type silicone resin or when the powder composition 17 is applied onto the first surfaces 12a of the plurality of light-emitting elements 12 and between the lateral surfaces 12c of the plurality of light-emitting elements 12 in S103 of applying the powder composition, the method preferably includes S105 of performing the polishing or grinding. Thus, the light-emitting device illustrated in FIG. 1B is obtained.

When the powder composition 17 is applied onto the first surfaces 12a of the plurality of light-emitting elements 12 and between the lateral surfaces 12c of the plurality of light-emitting elements 12 in S103 of applying the powder composition, the first covering member 18 disposed on the first surfaces 12a of the light-emitting elements 12 can be removed by S105 of performing the polishing or grinding to expose the first surfaces 12a of the light-emitting elements 12, and the upper surface 18a of the first covering member 18 between the lateral surfaces 12c of the plurality of light-emitting elements 12 can be made flush with the first surfaces 12a of the light-emitting elements 12, thereby obtaining a light-emitting device with higher luminance and more excellent contrast.

A method of polishing or grinding at least one of the first covering member 18 or the first surfaces 12a of the light-emitting elements 12 is not particularly limited, and a known method can be used.

### Method for Manufacturing Light-Emitting Device According to Second Embodiment

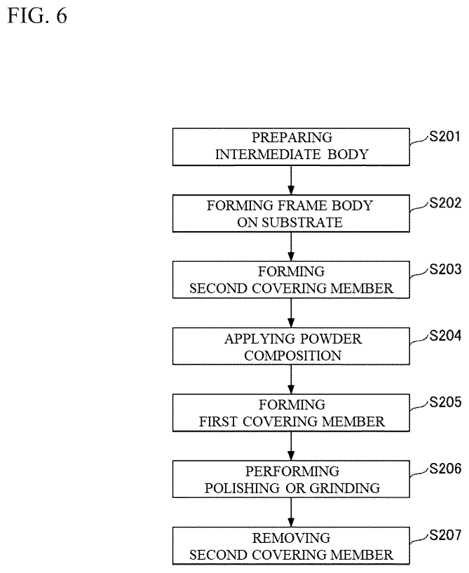

FIG. 6 is a flowchart showing an example of a method for manufacturing a light-emitting device according to the second embodiment. The method for manufacturing the light-emitting device according to the second embodiment includes S201 of preparing the intermediate body 10, S204 of applying a powder composition, and S205 of forming a first covering member. In addition to the steps described above, the method preferably further includes S202 of forming a frame body on a substrate, S203 of forming a second covering member, S206 of performing polishing or grinding, and S207 of removing the second covering member.

In the method for manufacturing the light-emitting device according to the second embodiment, S201 of preparing the intermediate body 10 is the same as S101 of preparing the intermediate body in the method for manufacturing the light-emitting device according to the first embodiment; however, the other steps such as S202 of forming the frame body on the substrate, S203 of forming the second covering member, S204 of applying the powder composition, S205 of forming the first covering member, S206 of performing the polishing or grinding, and S207 of removing the second covering member are different from those in the method for manufacturing the light-emitting device according to the first embodiment. The following describes an example of the method for manufacturing the light-emitting device according to the second embodiment while focusing on differences from the method for manufacturing the light-emitting device according to the first embodiment.

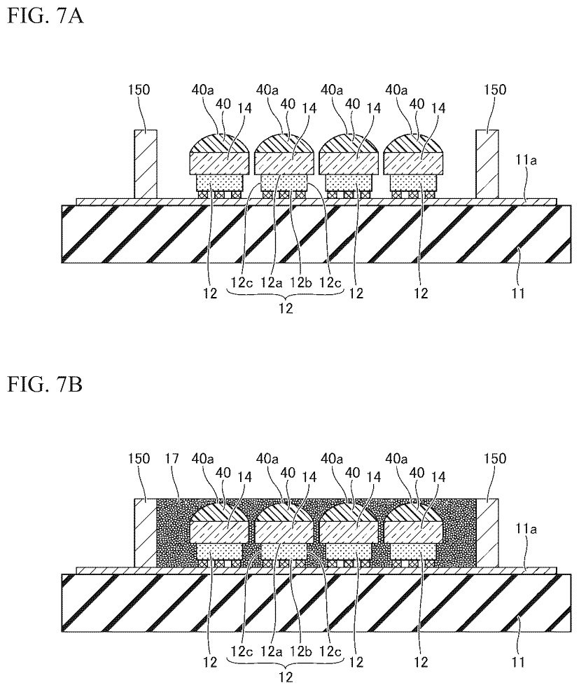

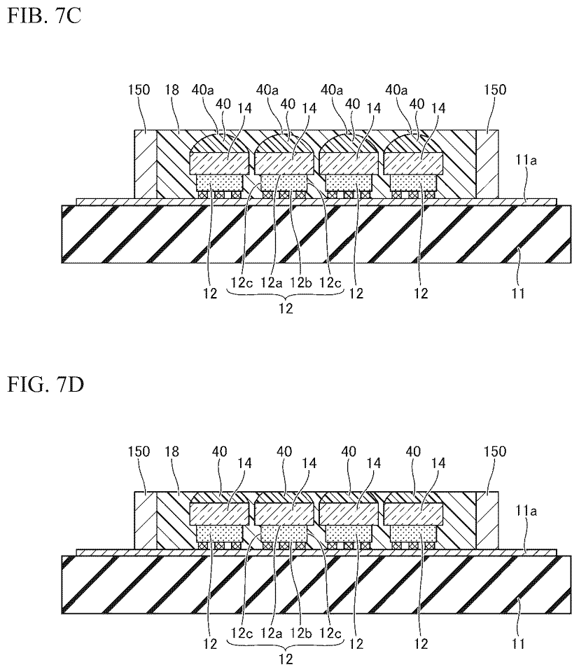

FIG. 7A is a schematic cross-sectional view illustrating an example of forming of a second covering member in the method for manufacturing the light-emitting device according to the second embodiment. FIG. 7B is a schematic cross-sectional view illustrating an example of applying of a powder composition in the method for manufacturing the light-emitting device according to the second embodiment. FIG. 7C is a schematic cross-sectional view illustrating an example of forming of a first covering member in the method for manufacturing the light-emitting device according to the second embodiment. FIG. 7D is a schematic cross-sectional view illustrating an example of performing of polishing or grinding in the method for manufacturing the light-emitting device according to the second embodiment.

### S202: Forming Frame Body on Substrate

S202 of forming the frame body on the substrate can be performed in the same manner as S102 of forming the frame body on the substrate in the method for manufacturing the light-emitting device according to the first embodiment, but the height from the upper surface of the substrate 11 to the top of the frame body 150 is preferably changed as follows.

In S202 of forming the frame body on the substrate, the height of the frame body 150 from the upper surface of the substrate 11 is preferably higher than the first surface 12a of the light-emitting element 12 as illustrated in FIG. 7B, for example. The height from the upper surface of the substrate 11 to the top of the frame body 150 may be lower than the height from the upper surface of the substrate 11 to a top 40a of a convex portion of a second covering member 40, but is preferably equal to or higher than the height from the upper surface of the substrate 11 to the top 40a of the convex portion of the second covering member 40. For example, when the height from the upper surface of the substrate 11 to the top 40a of the convex portion of the second covering member 40 is 400 μm, the height of the frame body 150 is in a range from 200 μm to 450 μm. Thus, in S204 of applying the powder composition, the powder composition 17 can suitably cover the entirety including the top 40a of the convex portion of the second covering member 40.

### S203: Forming Second Covering Member

In S203 of forming the second covering member, as illustrated in FIG. 7A, the second covering member 40 having a convex shape is formed on the first surfaces 12a of the plurality of light-emitting elements 12. S203 of forming the second covering member 40 is performed before S204 of applying the powder composition. S203 of forming the second covering member is preferably performed after S201 of preparing the intermediate body. S203 of forming the second covering member may be performed before or after S202 of forming the frame body on the substrate.

The term “convex” means that, in a cross-sectional view in the thickness direction of the light-emitting device 100, the surface in contact with the first surface 12a of the light-emitting elements 12 is a bottom surface of the second covering member 40 and the surface opposite to the surface in contact with the first surface 12a of the light-emitting elements 12 has a convex shape. The second covering member 40 is not particularly limited as long as it has a convex shape, but a shape having a convex curved surface (may be referred to as a “dome shape”) is preferable.

The second covering member 40 may be formed on the first surfaces 12a of all the light-emitting elements 12 of the plurality of light-emitting elements 12, or may be formed only on the first surfaces 12a of one or an arbitrary number of two or more light-emitting elements 12 of all the light-emitting elements 12 of the plurality of light-emitting elements 12.

The planar shape of the second covering member 40 can be various shapes such as a circle, an ellipse, a polygon such as a quadrangle or a hexagon, or a polygon with rounded corners. Among these, the planar shape of the second covering member 40 is preferably quadrangular, more preferably rectangular, still more preferably the same shape as the planar shape of the first surface 12a or the second surface 12b of the light-emitting elements 12.

The vertical and horizontal dimensions of the second covering member 40 and the thickness of the second covering member 40 (length from the contact surface of the second covering member 40 with the first surface 12a of the light-emitting element 12 to the top 40a of the convex portion of the second covering member 40) can be set arbitrarily. For example, in a plan view (top view), the vertical and horizontal dimensions of the second covering member 40 may be the same as the vertical and horizontal dimensions of the first surface 12a of the light-emitting element 12 in a plan view of the first surface 12a of the light-emitting element 12, at least one of the dimensions may be smaller, or at least one of the dimensions may be larger; however, the vertical and horizontal dimensions of the second covering member 40 are preferably 800 μm or more, more preferably 1,000 μm or more. From the viewpoint of uniformity of light emission intensity and reduction of light in the horizontal direction, the vertical and horizontal dimensions of the second covering member 40 are preferably 1,100 μm or less.

Examples of the material of the second covering member 40 include a resin. Any one of a thermosetting resin and a thermoplastic resin may be used as the resin as the material of the second covering member 40; however, in S205 of forming the first covering member, the thermoplastic resin is preferable because it can be easily removed by heating. Specific examples of the resin include epoxy resins, silicone resins, modified epoxy resins, modified silicone resins, polyester resins, polyimide resins, modified polyimide resins, polyphthalamide (PPA), polycarbonate resins, polyphenylene sulfide (PPS), liquid crystal polymer (LCP), ABS resins, phenol resins, acrylic resins, and PBT resins. These may be used alone or in combination of two or more. Among these, a Shore A hardness of 90 or less is preferable from the viewpoint of easy compression molding and easy pressing of the silicone resin in the first covering member 18.

Examples of the method for forming the second covering member 40 having a convex shape on the first surfaces 12a of the plurality of light-emitting elements 12 include a method in which the constituent resin material of the second covering member 40 is compression-molded or injection-molded to cover the first surfaces 12a of the light-emitting elements 12 (hereinafter, may be referred to as a “first method”) and a method in which the viscosity of the constituent resin material of the second covering member 40 is optimized and is dropped or drawn on the first surfaces 12a of the light-emitting elements 12 to control the shape by the surface tension of the constituent resin material of the second covering member 40 itself (hereinafter, may be referred to as a “second method”).

The second method is preferable in that the second covering member 40 can be formed by a simpler method without requiring a mold. In the second method, as a method of adjusting the viscosity of the constituent resin material of the second covering member 40, the viscosity of the constituent resin material of the second covering member 40 may be adjusted to a desired viscosity by using a known solvent, a material similar to the reflective member used for the first covering member 18, a material similar to the phosphor of the wavelength conversion member 14, a coloring agent, or the like, in addition to the adjustment by the viscosity of the constituent resin material of the second covering member 40 itself.

The amount of the constituent resin material of the second covering member 40 used is not particularly limited and can be appropriately selected depending on the dimensions of the first surface 12a of the light-emitting element 12. In S207 of removing the second covering member, the selection can be made appropriately in accordance with a desired depth or the like of the recessed portion 19 in the upper surface 18a of the first covering member 18 after the second covering member 40 is removed.

### S204: Applying Powder Composition

S204 of applying the powder composition can be performed in the same manner as S103 of applying the powder composition in the method for manufacturing the light-emitting device according to the first embodiment; however, applying the powder composition 17 onto the first surfaces 12a of the plurality of light-emitting elements 12 and between the lateral surfaces 12c of the plurality of light-emitting elements 12 is preferably changed to applying the powder composition 17 to all surfaces (including the top 40a of the convex portion of the second covering member 40) of the second covering member 40 other than the surface in contact with the light-emitting element 12 and between the lateral surfaces 12c of the plurality of light-emitting elements 12, or to applying the powder composition 17 onto the first surfaces 12a of the plurality of light-emitting elements 12, to all the surfaces (including the top 40a of the convex portion of the second covering member 40) of the second covering member 40 other than the surface in contact with the light-emitting element 12, and between the lateral surfaces 12c of the plurality of light-emitting elements 12, as illustrated in FIG. 7B. Thus, the recessed portion 19 can be formed in the upper surface 18a of the first covering member 18 in S206 of performing the polishing or grinding to be described below.

### S205: Forming First Covering Member

S205 of forming the first covering member can be performed in the same manner as S104 of forming the first covering member in the method for manufacturing the light-emitting device according to the first embodiment, but is preferably performed so that the second covering member 40 is not exposed when vibration is applied to the powder composition 17. In a case in which the second covering member 40 is exposed when vibration is applied to the powder composition 17, the first covering member 18 may be formed by applying vibration to the powder composition 17 once, performing S204 of applying the powder composition again, covering the second covering member 40 with the powder composition 17, and compressing and molding the powder composition 17 by applying pressure in the thickness direction of the substrate 11.

By S205 of forming the first covering member, the powder composition 17 is cured and the first covering member 18 is formed as illustrated in FIG. 7C.

### S206: Performing Polishing or Grinding

In S206 of performing the polishing or grinding, after S205 of forming the first covering member 18, the upper surface 18a of the first covering member 18 and at least a part of the surface of the second covering member 40 other than the surface in contact with the light-emitting elements 12 are polished or ground.

S206 of performing the polishing or grinding polishes or grinds the first covering member 18 disposed on the top 40a of the convex portion of the second covering member 40 in S205 of forming the first covering member by applying the powder composition onto the top 40a of the convex portion of the second covering member 40 and between the lateral surfaces 12c of the plurality of light-emitting elements 12 in S204 of applying the powder composition. At the same time, at least a part of the surface of the second covering member 40 other than the surface in contact with the light-emitting element 12 is polished or ground by appropriately adjusting the depth of polishing or grinding. Thus, the first covering member 18 disposed on the top 40a of the convex portion of the second covering member 40 can be removed and the second covering member 40 can be exposed. In S206 of performing the polishing or grinding, by polishing or grinding the second covering member 40 itself, the convex shape of the second covering member 40 changes. For example, in a cross-sectional view of the light-emitting device 100, the convex shape of the second covering member 40 is preferably changed from a dome shape to a quadrangular shape (for example, a square shape, a rectangular shape, a trapezoidal shape, or the like).

In S206 of performing the polishing or grinding, as illustrated in FIG. 7D, the entire second covering member 40 is not polished or ground, but is polished or ground to a position where the second covering member 40 remains at a desired depth (length from a contact surface of the second covering member 40 with the first surface 12a of the light-emitting element 12 to the top 40a of the convex portion of the second covering member 40).

In S206 of performing the polishing or grinding, the thickness of the second covering member 40 to be left after the polishing or polishing is not particularly limited, but is preferably in a range from 10 μm to 120 μm.

The method of polishing or grinding the first covering member 18 and the second covering member 40 is not particularly limited, and a known method can be used.

### S207: Removing Second Covering Member

In S207 of removing the second covering member, the second covering member 40 remaining after S206 of performing the polishing or grinding is removed. Thus, a part of the upper surface 18a of the first covering member 18 (region where the second covering member 40 is formed) illustrated in FIG. 3B becomes the recessed portion 19, and an inner bottom surface of the recessed portion 19 becomes the first surface 12a of the light-emitting element 12 or the upper surface 14a of the wavelength conversion member 14. In other words, the upper surface 18a of the first covering member 18 serves a convex portion with respect to the first surface 12a of the light-emitting element 12 or the upper surface 14a of the wavelength conversion member 14. Such a configuration can obtain a light-emitting device that can reduce the spread of light emitted from the light-emitting element 12 in a direction perpendicular to the thickness direction of the substrate 11 (the same direction as the surface direction of the first surface 12a of the light-emitting element 12) and increase the amount of light traveling straight in the thickness direction of the substrate 11 (direction perpendicular to the first surface 12a of the light-emitting element 12), and has higher luminance and more excellent contrast.

S207 of removing the second covering member may be performed simultaneously with S206 of performing the polishing or grinding, or S207 and S206 may be performed as separate steps.

When S207 of removing the second covering member and S206 of performing the polishing or grinding are performed at the same time, only the second covering member 40 may be removed by polishing or grinding at the time when the thickness of the second covering member 40 remaining after polishing or grinding (depth of the recessed portion 19 in the upper surface 18a of the first covering member 18) reaches a desired thickness.

When S207 of removing the second covering member and S206 of performing the polishing or grinding are performed as separate steps, the exposed second covering member 40 may be peeled off after S207 of removing the second covering member, or when the second covering member 40 is a thermoplastic resin, the second covering member 40 may be removed by heating.

### Method for Manufacturing Light-Emitting Device According to Third Embodiment

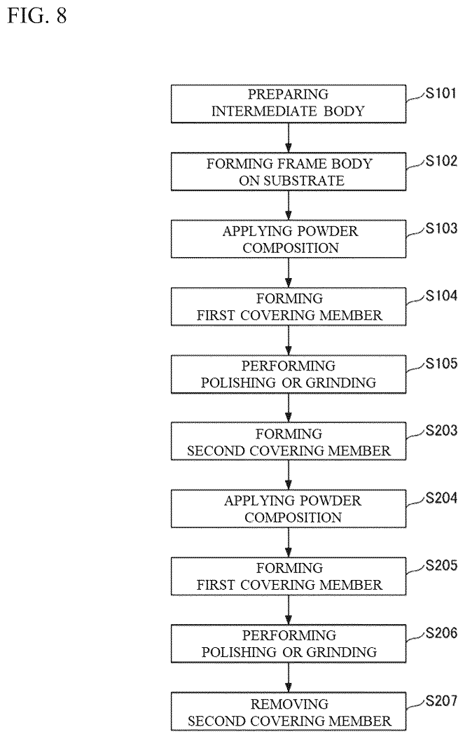

FIG. 8 is a flowchart illustrating an example of a method for manufacturing a light-emitting device according to the third embodiment. The method for manufacturing the light-emitting device according to the third embodiment is a method in which the method for manufacturing the light-emitting device according to the first embodiment and a part of the method for manufacturing the light-emitting device according to the second embodiment are performed in two stages, and specifically, performs S101 of preparing the intermediate body, S102 of forming the frame body on the substrate, S103 of applying the powder composition, S104 of forming the first covering member, and S105 of performing the polishing or grinding in the same manner as in the method for manufacturing the light-emitting device according to the first embodiment, and then performs S203 of forming the second covering member on the first surfaces 12a of the light-emitting elements 12, S204 of applying the powder composition, S205 of forming the first covering member, S206 of performing the polishing or grinding, and S207 of removing the second covering member in the same manner as in the method for manufacturing the light-emitting device according to the second embodiment.

Details of each step are as described in the method for manufacturing the light-emitting device according to the first embodiment and the method for manufacturing the light-emitting device according to the second embodiment.

### EXAMPLES

The present invention is described below in detail through examples and comparative examples; however, the present invention is not limited to these examples and comparative examples.

### First Example

In the first example, the light-emitting device illustrated in FIGS. 1A and 1B was manufactured as follows.

### S101: Preparing Intermediate Body

The wiring line 11a made of Au was formed in a predetermined pattern on the substrate 11 made of aluminum oxide ceramics. Separately, the wavelength conversion member 14 made of an yttrium-aluminum-garnet-based phosphor (for example, Y₃(Al,Ga)₅O₁₂:Ce) was bonded to the first surface 12a of a light-emitting diode made of a nitride semiconductor (InₓAl_{y}Ga_{1-x-y}N, 0≤x, 0≤y, x+y≤1) as the light-emitting element 12 having the first surface 12a serving as a light extraction surface, the second surface 12b opposite to the first surface 12a, and the lateral surface 12c connecting the first surface 12a and the second surface 12b. The light-emitting element 12 used had a rectangular shape with a length of 1,000 μm, a width of 1,000 m, and a thickness of 200 μm in a plan view. The wavelength conversion member 14 used had a rectangular shape with a length of 1,200 μm, a width of 1,200 μm, and a thickness of 150 μm in a plan view. Subsequently, an intermediate body was prepared in which four light-emitting elements 12 were disposed on the wiring lines 11a of the substrate 11 in a line at equal intervals in the first direction at a pitch of 300 μm via bumps. At this time, the first electrodes or the second electrodes of the light-emitting elements 12 were connected to the wiring lines 11a provided on the substrate 11 via a bonding member.

### S102: Forming Frame Body on Substrate

As illustrated in FIG. 5B, a frame body 150 made of an epoxy resin and having a height of 400 μm was formed on the wiring lines 11a of the substrate 11. The frame body 150 has a substantially rectangular frame shape surrounding the plurality of light-emitting elements 12.

### S103: Applying Powder Composition

A powder composition 17 containing titanium oxide of 75 mass % (mixture with a particle diameter in a range from 0.05 μm to 1 μm) as a reflective member and a spherical methyl silicone resin of 25 mass % (mixture with a particle diameter in a range from 1 μm to 150 μm and a refractive index of 1.41) as a silicone resin powder was prepared. Subsequently, as illustrated in FIG. 5C, the powder composition 17 was applied from above the first surfaces 12a of the plurality of light-emitting elements 12 through the sieve 30, and was located on the substrate 11, between the lateral surfaces 12c of the plurality of light-emitting elements 12, and between the lateral surface of the frame body 150 on which the light-emitting elements 12 are disposed and the lateral surfaces 12c of the light-emitting elements 12. At this time, the powder composition 17 was applied until it covers the wavelength conversion member 14.

### S104: Forming First Covering Member

As illustrated in FIGS. 5E and 5G, after the vibration v is applied to the powder composition 17, the pressure p (10 MPa) in the thickness direction of the substrate 11 was applied for five minutes to compression-mold the powder composition 17, thereby forming the first covering member 18.

### S105: Performing Polishing or Grinding

Subsequently, the first covering member 18 was ground so that the upper surface 18a of the first covering member 18 and the first surfaces 12a of the light-emitting elements 12 are flush with each other, thereby obtaining the light-emitting device of the first example.

### First Comparative Example

A light-emitting device of a first comparative example was obtained in the same manner as in the first example except that the powder composition 17 was applied by scooping the powder composition 17 with a spatula and disposing the powder composition 17 onto the substrate 11 without using the sieve 30 in S103 that was used the first example.

### Second Comparative Example

A light-emitting device of a second comparative example was obtained in the same manner as in the first example except that the vibration v was not applied to the powder composition 17 in S104 of forming the first covering member of the first example.

### Comparative Example 3

A light-emitting device of a third comparative example was obtained in the same manner as in the first example except that the pressure p was not applied to the powder composition 17 in S104 of forming the first covering member of the first example.

### Evaluation of Luminance Using Upper Surface 14a of Wavelength Conversion Member 14 as Light-Emitting Area

The luminance of the light-emitting devices of the first example and the first to third comparative examples were measured using a color luminance meter (Pro Metric) with the upper surface 14a of the wavelength conversion member 14 as the light-emitting area. From the measured values, the luminance was evaluated based on the following evaluation criteria. The results are shown in Table 1 below.

### Evaluation Criteria of Luminance

A: Luminance is 90 cd/mm² or more
B: Luminance is in a range from 85 cd/mm² to less than 90 cd/mm²
C: Luminance is less than 85 cd/mm²
   Evaluation of Ratio of Luminance of Upper Surface 14a of Turned-Off Adjacent Wavelength Conversion Member 14 to Luminance when Upper Surface 14a of Wavelength Conversion Member 14 is Used as Light-Emitting Area

In the light-emitting devices of the first example and the first to third comparative examples, the ratio (contrast) of the luminance of the upper surface 14a of the turned-off adjacent wavelength conversion member 14 to the luminance when the upper surface 14a of the wavelength conversion member 14 is used as the light-emitting area was measured using a color luminance meter (ProMetric). From the measured values, the contrast was evaluated based on the following evaluation criteria. The results are shown in Table 1 below.

### Evaluation Criteria of Contrast

A: Contrast is 125:1% or more
B: Contrast is 110:1% or more and less than 125:1%
C: Contrast is less than 110:1%

TABLE 1

| | | | First | Second | Third |
|---|---|---|---|---|---|
| | | | compar- | compar- | compar- |
| | | First | ative | ative | ative |
| | | example | example | example | example |
| S103 of putting | Sieve | Present | None | Present | Present |
| powder composition | | | | | |
| S104 of forming | Vibration | Present | Present | None | Present |
| first covering | Compression | Present | Present | Present | None |
| member | molding | | | | |
| Light-emitting | Luminance | A | C | C | C |
| device | Contrast | A | C | C | C |

As described above, the present invention has been described based on specific embodiments, but these are merely presented as examples, and the present invention is not limited to the above-described embodiments. The above embodiments can be embodied in various other forms, and various combinations, omissions, substitutions, additions, modifications, and the like can be made without departing from the spirit of the invention. These embodiments and variations thereof are included in the scope and spirit of the invention and are within the scope of the invention described in the claims and equivalents thereof.

1. A method for manufacturing a light-emitting device, comprising:
preparing an intermediate body comprising:
a substrate, and
a plurality of light-emitting elements disposed on the substrate, each comprising a first surface serving as a light extraction surface, a second surface opposite to the first surface, and a lateral surface connecting the first surface and the second surface;
applying a powder composition comprising a reflective member and a silicone resin powder from above the first surfaces of the plurality of light-emitting elements through a sieve to locate the powder composition on the substrate and between the lateral surfaces of the plurality of light-emitting elements; and
forming a first covering member by applying vibration to the powder composition and subsequently applying pressure in a thickness direction of the substrate to perform compression molding.

2. The method for manufacturing a light-emitting device according to claim 1, wherein:
the preparing of the intermediate body further comprises disposing a wavelength conversion member in contact with the first surface of the light-emitting element or above the first surface of the light-emitting element.

3. The method for manufacturing a light-emitting device according to claim 1, further comprising:
before the applying of the powder composition, forming a frame body surrounding the plurality of light-emitting elements on the substrate.

4. The method for manufacturing a light-emitting device according to claim 1, further comprising:
before the applying of the powder composition, forming a second covering member having a convex shape on the first surfaces of the plurality of light-emitting elements.

5. The method for manufacturing a light-emitting device according to claim 4, further comprising:
after the forming of the first covering member, polishing or grinding an upper surface of the first covering member and at least a part of a surface of the second covering member other than a surface in contact with the light-emitting elements; and
removing the second covering member.

6. The method for manufacturing a light-emitting device according to claim 1, wherein:
in the applying of the powder composition, the powder composition is applied onto the first surfaces of the plurality of light-emitting elements.

7. The method for manufacturing a light-emitting device according to claim 1, wherein:
in the applying of the powder composition, a content of the reflective member in the powder composition is 70 volume % or more.

8. The method for manufacturing a light-emitting device according to claim 1, wherein:
in the applying of the powder composition, the reflective member has a particle diameter in a range from 0.05 μm to 1 μm and the silicone resin powder has a particle diameter in a range from 1 μm to 150 μm.

9. The method for manufacturing a light-emitting device according to claim 1, wherein:
the forming of the first covering member comprises:
heating the powder composition to a temperature equal to or higher than a melting temperature of the silicone resin powder and equal to or lower than a curing temperature of the silicone resin powder, and
curing the powder composition at a temperature equal to or higher than the curing temperature of the silicone resin powder.

10. The method for manufacturing a light-emitting device according to claim 1, wherein:
in the forming of the first covering member, the powder composition is compression-molded such that a density of the reflective member in the first covering member is 2.0 g/cm³ or more.

11. The method for manufacturing a light-emitting device according to claim 1, further comprising:
after the forming of the first covering member, polishing or grinding at least one of an upper surface of the first covering member or the first surface of the light-emitting element so that the upper surface of the first covering member and the first surface of the light-emitting element are flush with each other.

12. Alight-emitting device comprising:
a substrate;
a plurality of light-emitting elements mounted on the substrate, each comprising a first surface serving as a light extraction surface, a second surface opposite to the first surface, and a lateral surface connecting the first surface and the second surface; and
a first covering member located on the substrate and between the lateral surfaces of the plurality of light-emitting elements, wherein:
the first covering member comprises a reflective member and a silicone resin,
the silicone resin has a refractive index of 1.45 or less,
a density of the reflective member in the first covering member is 2.0 g/cm³ or more, and
a reflectance of the first covering member is 70% or more with respect to light at an emission peak of the light-emitting elements.

13. The light-emitting device according to claim 12, wherein:
an upper surface of the first covering member comprises polishing or grinding marks.

14. The light-emitting device according to claim 12, further comprising:
a wavelength conversion member disposed on the first surface of the light-emitting element or above the first surface of the light-emitting element.

15. The light-emitting device according to claim 12, wherein:
the light-emitting device further comprises a frame body surrounding the plurality of light-emitting elements, and
the first covering member is further located between the lateral surfaces of the plurality of light-emitting elements and a lateral surface of the frame body.

16. The light-emitting device according to claim 12, wherein:
an upper surface of the first covering member is flush with the first surface of the light-emitting element.

17. The light-emitting device according to claim 14, wherein:
an upper surface of the first covering member is higher than the first surface of the light-emitting element or an upper surface of the wavelength conversion member,
in a cross-sectional view, the upper surface of the first covering member comprises a recessed portion, and an inner bottom of the recessed portion is the first surface of the light-emitting element or the upper surface of the wavelength conversion member.

18. A method for manufacturing a light-emitting device, comprising:
preparing an intermediate body comprising:
a substrate, and
a plurality of light-emitting elements disposed on the substrate, each comprising a first surface serving as a light extraction surface, a second surface opposite to the first surface, and a lateral surface connecting the first surface and the second surface;
applying a powder composition between the lateral surfaces of the plurality of light-emitting elements; and
forming a first covering member by applying vibration to the powder composition and subsequently applying pressure in a thickness direction of the substrate to perform compression molding.
